(19) United States
(12) Patent Application Publication
(10) Pub. No.: US 2026/0223729 A1
(43) Pub. Date: Jul. 30, 2026

(54) ALIGNMENT METHOD OF SEMICONDUCTOR CHIP, BONDING METHOD, SEMICONDUCTOR DEVICE, AND ELECTRONIC COMPONENT MANUFACTURING SYSTEM

(71) Applicants: YAMAHA ROBOTICS HOLDINGS CO., LTD., Tokyo (JP); TOHOKU UNIVERSITY, Miyagi (JP)

(72) Inventors: Hayato Hishinuma, Tokyo (JP); Hiroshi KIKUCHI, Tokyo (JP); Yuta Tobari, Tokyo (JP); Takafumi FUKUSHIMA, Miyagi (JP)

(73) Assignees: YAMAHA ROBOTICS HOLDINGS CO., LTD., Tokyo (JP); TOHOKU UNIVERSITY, Miyagi (JP)

(21) Appl. No.: 19/145,892

(22) PCT Filed: Dec. 19, 2023
(86) PCT No.: PCT/JP2023/045394

§ 371 Date: Jul. 3, 2025

(30) Foreign Application Priority Data
Jan. 6, 2023 (JP) 2023-000829

(51) Int. Cl. H10W 80/00; B23K 20/02; B23K 101/40; H10P 72/00; H10W 20/00; H10W 70/05

(52) U.S. Cl. CPC H10W 80/165; B23K 20/023; H10P 72/0438; H10W 20/023; H10W 70/095; B23K 2101/40

(57) ABSTRACT

A bonding method of laminating and bonding a semiconductor chip to a wafer includes: a thin film forming process of coating titanium oxide onto a surface of the wafer and an opposing surface of the semiconductor chip to form a surface thin film and an opposing surface thin film; a hydrophilization process of irradiating light onto the surface thin film and the opposing surface thin film to perform hydrophilization; a droplet attaching process of attaching a droplet to a hydrophilization region of the wafer; a self-alignment process of loading the semiconductor chip onto the droplet and causing a chip hydrophilization region of the semiconductor chip to self-align with the hydrophilization region of the wafer by surface tension of the droplet; and a bonding process of bringing the chip hydrophilization region into contact with the hydrophilization region to hydrophilically bond the chip hydrophilization region and the hydrophilization region.

### TECHNICAL FIELD

The present invention relates to an alignment method of a semiconductor chip to be laminated, a bonding method, a semiconductor device, and a configuration of an electronic component manufacturing system.

### BACKGROUND ART

In a method being used, a semiconductor chip is laminated onto a semiconductor chip with solder bumps formed on electrodes and is pressed to be temporarily bonded, then heating is performed in a reflow furnace, and self-alignment is performed by surface tension and interfacial tension when the solder becomes liquid. Afterward, the temperature is lowered to solidify the solder to laminate and bond the semiconductor chip (see, for example, Patent Document 1). In this method, after solidifying the solder, resin is filled in the gap of the semiconductor chips to perform sealing, and a laminated semiconductor device is formed.

In addition, in a proposed method, multiple semiconductor chips are temporarily adhered to a carrier substrate, and the carrier substrate is pressed against other semiconductor chips bonded on a support substrate to laminate and bond the semiconductor chips to the other semiconductor chips (see, for example, Patent Document 2). In this method, after forming a thin film of silicon dioxide on the entire surface of the carrier substrate, by removing portions other than a temporary adhesion region by etching, a thin film of silicon dioxide with hydrophilicity is formed in the temporary adhesion region. Then, water is dropped onto the temporary adhesion region to form a water film, semiconductor chips with surfaces hydrophilized by the same method as described above are loaded onto the water film, the positions of the semiconductor chips are automatically aligned by the surface tension of water, and the semiconductor chips are temporarily adhered to the carrier substrate by the adsorption force of water. In this method, after the lamination bonding between the semiconductor chips and the other semiconductor chips is completed, the water between the carrier substrate and the semiconductor chips is evaporated by heating, and then the carrier substrate is removed from the semiconductor chips.

In the method described in Patent Document 2, the bonding between the semiconductor chips and the other semiconductor chips is performed by pressure-connecting micro bumps formed on the electrodes of the semiconductor chips, and an insulating adhesive is filled in the gap between the semiconductor chips and the other semiconductor chips.

### RELATED ART DOCUMENTS

### Patent Documents

Patent Document 1: Japanese Patent Application Laid-Open No. 2009-110995
Patent Document 2: International Publication No. 2006/077739

### SUMMARY OF INVENTION

### Problem to be Solved by Invention

However, in the related art described in Patent Document 1, although self-alignment of the laminated semiconductor chip can be performed with the molten solder, the process is complex, requiring filling resin into the gap after solidifying the solder, and there is room for improvement.

In addition, in the related art described in Patent Document 2, the positions of the carrier substrate and the semiconductor chips are automatically aligned by the surface tension of water. However, actually, the positions of the other semiconductor chips to be laminated and bonded and the semiconductor chips are not automatically aligned, and there is a possibility that the positions of the semiconductor chip to be laminated and bonded and the other semiconductor chips may be misaligned.

Thus, the present invention aims to improve the alignment accuracy of a semiconductor chip to be laminated and bonded.

### Means for Solving Problem

An alignment method of the present invention is an alignment method of a first semiconductor chip in a case of laminating and bonding the first semiconductor chip to a plate-shaped electronic component, and includes: a thin film forming process of coating a photoexcited hydrophilization reactant onto a surface of the electronic component and an opposing surface of the first semiconductor chip that is opposed to the surface, to form a surface thin film and an opposing surface thin film; a hydrophilization process of irradiating light onto a hydrophilization region, which is a part of the surface thin film, and a chip hydrophilization region of the opposing surface thin film that is opposed to the hydrophilization region, to hydrophilize the hydrophilization region and the chip hydrophilization region; a droplet attaching process of attaching a droplet to the hydrophilized hydrophilization region of the electronic component; and a self-alignment process of loading the hydrophilized chip hydrophilization region of the first semiconductor chip onto the droplet, and causing the chip hydrophilization region of the first semiconductor chip to self-align with respect to the hydrophilization region of the electronic component by surface tension of the droplet.

In this manner, since the position of the first semiconductor chip is self-aligned with respect to the electronic component to be laminated and bonded by the surface tension of the droplet, the electronic component and the first semiconductor chip can be aligned with high accuracy.

In the alignment method of the present invention, the hydrophilization region and the chip hydrophilization region may be regions having a same external shape and smaller than an external shape of the first semiconductor chip.

Accordingly, the alignment accuracy between the electronic component and the first semiconductor chip can be improved.

In the alignment method of the present invention, the photoexcited hydrophilization reactant may be selected from any one of titanium oxide, tungsten trioxide, silver bromide, silver chloride, silicon dioxide, nitrogen-doped silicon carbide, silicon nitride, or carbon-doped silicon monoxide. The droplet may be composed of a liquid selected from any one of hydrogen water, ozone water, carbon water, alkaline electrolytic water, or fine bubble water. The light may be ultraviolet light.

Accordingly, alignment between the electronic component and the first semiconductor chip can be performed by a simple method.

In the alignment method of the present invention, the electronic component may be a wafer, a second semiconductor chip different from the first semiconductor chip, or a substrate.

Accordingly, alignment between various types of electronic components and the first semiconductor chip can be performed by a simple method.

A bonding method of the present invention is a bonding method of laminating and bonding a first semiconductor chip to a plate-shaped electronic component, and includes: a thin film forming process of coating a photoexcited hydrophilization reactant onto a surface of the electronic component and an opposing surface of the first semiconductor chip that is opposed to the surface, to form a surface thin film and an opposing surface thin film; a hydrophilization process of irradiating light onto a hydrophilization region, which is a part of the surface thin film, and a chip hydrophilization region of the opposing surface thin film that is opposed to the hydrophilization region, to hydrophilize the hydrophilization region and the chip hydrophilization region; a droplet attaching process of attaching a droplet to the hydrophilized hydrophilization region of the electronic component; a self-alignment process of loading the hydrophilized chip hydrophilization region of the first semiconductor chip onto the droplet, and causing the chip hydrophilization region of the first semiconductor chip to self-align with respect to the hydrophilization region of the electronic component by surface tension of the droplet; and a bonding process of bringing the hydrophilized chip hydrophilization region of the opposing surface thin film into contact with the hydrophilized hydrophilization region of the surface thin film to hydrophilically bond the hydrophilization region of the surface thin film and the chip hydrophilization region of the opposing surface thin film.

In this manner, since the position of the first semiconductor chip is self-aligned with respect to the electronic component to be laminated and bonded by the surface tension of the droplet, and the electronic component and the first semiconductor chip are bonded in this state, the electronic component and the first semiconductor chip can be bonded with high alignment accuracy.

In the bonding method of the present invention, the hydrophilization region and the chip hydrophilization region may be regions having a same external shape and smaller than an external shape of the first semiconductor chip.

Accordingly, the alignment accuracy between the electronic component and the first semiconductor chip can be improved.

The bonding method of the present invention may further include a thermal diffusion bonding process. The electronic component may include at least one electrode protruding from the surface. The first semiconductor chip may include at least one opposing electrode protruding from the opposing surface at a position opposed to each of the electrodes. The thin film forming process may coat the photoexcited hydrophilization reactant onto the surface to form the surface thin film with a thickness same as a protruding height of each of the electrodes in a region of the surface not including each of the electrodes, and coat the photoexcited hydrophilization reactant onto the opposing surface to form the opposing surface thin film with a thickness same as a protruding height of each of the opposing electrodes in a region of the opposing surface not including each of the opposing electrodes. The hydrophilization process may hydrophilize the hydrophilization region of the surface thin film and the chip hydrophilization region of the opposing surface thin film. The bonding process may bring the hydrophilized chip hydrophilization region of the opposing surface thin film into contact with the hydrophilized hydrophilization region of the surface thin film to hydrophilically bond the hydrophilization region of the surface thin film and the chip hydrophilization region of the opposing surface thin film, and form a bonding body in which each tip surface of each of the electrodes and each tip surface of each of the opposing electrodes are in contact with each other. The thermal diffusion bonding process may heat the bonding body to bond, by thermal diffusion, each tip surface of each of the electrodes and each tip surface of each of the opposing electrodes which are in contact with each other.

In this manner, since the surface thin film of the electronic component and the tip surface of the electrode of the electronic component, which are formed at the same height, are bonded respectively to the opposing surface thin film of the first semiconductor chip and the tip surface of the opposing electrode of the first semiconductor chip, which are formed at the same height, by hydrophilic bonding and thermal diffusion bonding, no gap is formed between the electronic component and the first semiconductor chip after bonding, and it is not required to fill a gap with an adhesive or the like. Thus, a semiconductor device with high bonding quality can be manufactured by a simple method.

The bonding method of the present invention may further include: a through electrode forming process of forming, in the electronic component formed with the surface thin film, at least one through electrode penetrating through the electronic component and the surface thin film in a thickness direction of the electronic component; an opposing through electrode forming process of forming, in the first semiconductor chip formed with the opposing surface thin film, at least one opposing through electrode that penetrates through the first semiconductor chip and the opposing surface thin film in a thickness direction of the first semiconductor chip and is opposed to the through electrode; and a thermal diffusion bonding process. The bonding process may bring the hydrophilized chip hydrophilization region of the opposing surface thin film into contact with the hydrophilized hydrophilization region of the surface thin film to hydrophilically bond the hydrophilization region of the surface thin film and the chip hydrophilization region of the opposing surface thin film, and form a bonding body in which each tip surface of each of the through electrodes and each tip surface of each of the opposing through electrodes are in contact with each other. The thermal diffusion bonding process may heat the bonding body to bond, by thermal diffusion, each tip surface of each of the through electrodes and each tip surface of each of the opposing through electrodes which are in contact with each other.

In this manner, since the surface thin film of the electronic component and the tip surface of the through electrode are bonded respectively to the opposing surface thin film of the first semiconductor chip and the tip surface of the opposing through electrode by hydrophilic bonding and thermal diffusion bonding, no gap is formed between the electronic component and the first semiconductor chip after bonding, and it is not required to fill a gap with an adhesive or the like. Thus, a semiconductor device with high bonding quality can be manufactured by a simple method.

In the bonding method of the present invention, the photoexcited hydrophilization reactant may be selected from any one of titanium oxide, tungsten trioxide, silver bromide, silver chloride, silicon dioxide, nitrogen-doped silicon carbide, silicon nitride, or carbon-doped silicon monoxide. The droplet may be composed of a liquid selected from any one of hydrogen water, ozone water, carbon water, alkaline electrolytic water, or fine bubble water. The light may be ultraviolet light.

Accordingly, alignment between the electronic component and the first semiconductor chip can be performed by a simple method.

In the bonding method of the present invention, the electronic component may be a wafer, a second semiconductor chip different from the first semiconductor chip, or a substrate.

Accordingly, bonding between various types of electronic components and the first semiconductor chip can be performed by a simple method.

A semiconductor device of the present invention is obtained by bonding the electronic component and the first semiconductor chip by the bonding method above.

A semiconductor device with high bonding quality can be provided by a simple method.

An electronic component manufacturing system of the present invention is an electronic component manufacturing system laminating and bonding a first semiconductor chip to a plate-shaped electronic component, and includes a thin film forming apparatus, a hydrophilization apparatus, and a bonding apparatus. The thin film forming apparatus coats a photoexcited hydrophilization reactant onto a surface of the electronic component and an opposing surface of the first semiconductor chip that is opposed to the surface to form a surface thin film and an opposing surface thin film, and supplies the electronic component formed with the surface thin film and the first semiconductor chip formed with the opposing surface thin film to the hydrophilization apparatus. The hydrophilization apparatus irradiates light onto a hydrophilization region, which is a part of the surface thin film, and a chip hydrophilization region of the opposing surface thin film that is opposed to the hydrophilization region to hydrophilize the hydrophilization region and the chip hydrophilization region, and supplies the hydrophilized electronic component and the hydrophilized first semiconductor chip to the bonding apparatus. The bonding apparatus bonds the first semiconductor chip to the electronic component supplied from the hydrophilization apparatus, and includes: a stage that adsorbs and fixes the electronic component; a collet that holds and releases the first semiconductor chip; a dispenser that attaches a droplet to the surface of the electronic component; a bonding head that moves the collet in each of a direction along the stage and a direction contacting and separating from the stage; a dispenser head that moves the dispenser in each of a direction along the stage and a direction contacting and separating from the stage; a pressing device that presses the first semiconductor chip against the electronic component adsorbed and fixed on the stage; and a control part that adjusts operations of the collet, the dispenser, the bonding head, the dispenser head, and the pressing device. The control part includes a processor that performs information processing. The processor is configured to: attach, by the dispenser, the droplet to the hydrophilized hydrophilization region of the electronic component adsorbed and fixed on the stage; load, by the collet, the hydrophilized chip hydrophilization region of the first semiconductor chip onto the droplet, and cause the chip hydrophilization region of the first semiconductor chip to self-align with respect to the hydrophilization region of the electronic component by surface tension of the droplet; and press, by the pressing device, the hydrophilized chip hydrophilization region of the opposing surface thin film against the hydrophilized hydrophilization region of the surface thin film to hydrophilically bond the hydrophilization region of the surface thin film and the chip hydrophilization region of the opposing surface thin film.

In this manner, since the position of the first semiconductor chip is self-aligned with respect to the electronic component to be laminated and bonded by the surface tension of the droplet, and the electronic component and the first semiconductor chip are aligned in this state, the electronic component and the first semiconductor chip can be bonded with high alignment accuracy.

In the electronic component manufacturing system of the present invention, the hydrophilization region and the chip hydrophilization region may be regions having a same external shape and smaller than an external shape of the first semiconductor chip.

Accordingly, the alignment accuracy between the electronic component and the first semiconductor chip can be improved.

The electronic component manufacturing system of the present invention may further include a heating apparatus. The electronic component may include at least one electrode protruding from the surface. The first semiconductor chip may include at least one opposing electrode protruding from the opposing surface at a position opposed to each of the electrodes. The thin film forming apparatus may coat the photoexcited hydrophilization reactant onto the surface to form the surface thin film with a thickness same as a protruding height of each of the electrodes in a region of the surface not including each of the electrodes, and coat the photoexcited hydrophilization reactant onto the opposing surface to form the opposing surface thin film with a thickness same as a protruding height of each of the opposing electrodes in a region of the opposing surface not including each of the opposing electrodes. The hydrophilization apparatus may hydrophilize the hydrophilization region of the surface thin film and the chip hydrophilization region of the opposing surface thin film. The processor may be configured to press, by the pressing device, the hydrophilized chip hydrophilization region of the opposing surface thin film against the hydrophilized hydrophilization region of the surface thin film to hydrophilically bond the hydrophilization region of the surface thin film and the chip hydrophilization region of the opposing surface thin film, and form a bonding body in which each tip surface of each of the electrodes and each tip surface of each of the opposing electrodes are in contact with each other. The heating apparatus may heat the bonding body to bond, by thermal diffusion, each tip surface of each of the electrodes and each tip surface of each of the opposing electrodes which are in contact with each other.

In this manner, since the surface thin film of the electronic component and the tip surface of the electrode of the electronic component, which are formed at the same height, are bonded respectively to the opposing surface thin film of the first semiconductor chip and the tip surface of the opposing electrode of the first semiconductor chip, which are formed at the same height, by hydrophilic bonding and thermal diffusion bonding, no gap is formed between the electronic component and the first semiconductor chip after bonding, and it is not required to fill a gap with an adhesive or the like. Thus, a semiconductor device with high bonding quality can be manufactured by a simple method.

The electronic component manufacturing system of the present invention may further include an electrode forming apparatus and a heating apparatus. The thin film forming apparatus may coat the photoexcited hydrophilization reactant onto the surface of the electronic component and the opposing surface of the first semiconductor chip that is opposed to the surface to form the surface thin film and the opposing surface thin film, and supply the electronic component formed with the surface thin film and the first semiconductor chip formed with the opposing surface thin film to the electrode forming apparatus. The electrode forming apparatus may form, in the electronic component formed with the surface thin film, at least one through electrode penetrating through the electronic component and the surface thin film in a thickness direction of the electronic component, and form, in the first semiconductor chip formed with the opposing surface thin film, at least one opposing through electrode that penetrates through the first semiconductor chip and the opposing surface thin film in a thickness direction of the first semiconductor chip and is opposed to the through electrode. The hydrophilization apparatus may hydrophilize the hydrophilization region of the surface thin film and the chip hydrophilization region of the opposing surface thin film. The processor may be configured to press, by the pressing device, the hydrophilized chip hydrophilization region of the opposing surface thin film against the hydrophilized hydrophilization region of the surface thin film to hydrophilically bond the hydrophilization region of the surface thin film and the chip hydrophilization region of the opposing surface thin film, and form a bonding body in which each tip surface of each of the through electrodes and each tip surface of each of the opposing through electrodes are in contact with each other. The heating apparatus may heat the bonding body to bond, by thermal diffusion, each tip surface of each of the through electrodes and each tip surface of each of the opposing through electrodes which are in contact with each other.

In this manner, since the surface thin film of the electronic component and the tip surface of the through electrode are bonded respectively to the opposing surface thin film of the first semiconductor chip and the tip surface of the opposing through electrode by hydrophilic bonding and thermal diffusion bonding, no gap is formed between the electronic component and the first semiconductor chip after bonding, and it is not required to fill a gap with an adhesive or the like. Thus, a semiconductor device with high bonding quality can be manufactured by a simple method.

### Effects of Invention

The present invention is capable of improving the alignment accuracy of a semiconductor chip to be laminated and bonded.

### BRIEF DESCRIPTION OF THE DRAWINGS

FIG. 1 is a flowchart showing an alignment method and a bonding method of an embodiment.

FIG. 2 is a cross-sectional view of a semiconductor chip.

FIG. 3 is cross-sectional views of the semiconductor chip showing a state (left view) in which an opposing thin film is formed on an opposing surface of the semiconductor chip shown in FIG. 2, and a state (right view) in which the opposing thin film formed on tip surfaces of opposing electrodes of the semiconductor chip are removed.

FIG. 4 is a view illustrating a hydrophilization process of hydrophilizing a chip hydrophilization region of the semiconductor chip.

FIG. 5 is a plan view of the semiconductor chip shown in FIG. 4.

FIG. 6 is a plan view and an A-A cross-section of a wafer to which the semiconductor chip shown in FIG. 2 is bonded.

FIG. 7 is a plan view showing a state in which a surface thin film is formed on a surface of the wafer shown in FIG. 6, and a hydrophilization region is hydrophilized.

FIG. 8 is a cross-sectional view of the wafer shown in FIG. 7, and is a B-B cross-section shown in FIG. 7.

FIG. 9 is a cross-sectional view showing a state in which a droplet is attached to the hydrophilized hydrophilization region of the wafer shown in FIG. 8.

FIG. 10 is a cross-sectional view of the wafer and the semiconductor chip, showing a state in which the semiconductor chip with the hydrophilized chip hydrophilization region shown in FIG. 4 is inverted and loaded onto the droplet shown in FIG. 9.

FIG. 11 is a cross-sectional view of the wafer and the semiconductor chip, showing a state in which positions of each opposing electrode of the semiconductor chip and the electrodes of the wafer are aligned by self-alignment of the droplet from the state shown in FIG. 10.

FIG. 12 is a cross-sectional view of the wafer and the semiconductor chip, showing a state in which the semiconductor chip is pressed toward the wafer from the state shown in FIG. 10.

FIG. 13 is a cross-sectional view of the wafer and the semiconductor chip, showing a bonding body in which the chip hydrophilization region of the semiconductor chip and the hydrophilization region of the wafer are hydrophilically bonded, and the tip surfaces of the electrodes of the wafer and the tip surfaces of the opposing electrodes of the semiconductor chip are in contact with each other.

FIG. 14 is a plan view showing another shape of the opposing thin film of the semiconductor chip.

FIG. 15 is a plan view showing another shape of the opposing thin film of the semiconductor chip.

FIG. 16 is a view illustrating a configuration of an electronic component manufacturing system of the embodiment.

FIG. 17 is a system diagram showing a configuration of a bonding apparatus shown in FIG. 16.

FIG. 18 is a system diagram showing a configuration of a pressing device of the bonding apparatus shown in FIG. 16.

FIG. 19 is a view illustrating an operation of the bonding apparatus shown in FIG. 16, showing an operation of attaching a droplet to the hydrophilized hydrophilization region of the surface of the wafer by a dispenser.

FIG. 20 is view illustrating an operation of the bonding apparatus shown in FIG. 16, showing a state in which the semiconductor chip is moved to a bonding position of the wafer by a collet.

FIG. 21 is a view illustrating an operation of the bonding apparatus shown in FIG. 16, showing a state in which the semiconductor chip is loaded onto the droplet by the collet.

FIG. 22 is a view illustrating an operation of the bonding apparatus shown in FIG. 16, showing a state in which the pressing device is moved above the semiconductor chip.

FIG. 23 is a view illustrating an operation of the bonding apparatus shown in FIG. 16, showing a state in which the semiconductor chip is pressed against the surface of the wafer by the pressing device.

FIG. 24 is a view illustrating an operation of the bonding apparatus shown in FIG. 16, showing a state in which the pressing device is raised after the pressing operation.

FIG. 25 is a flowchart showing a bonding method of another embodiment.

FIG. 26 is a cross-sectional view of another semiconductor chip to be laminated and bonded, showing a state in which an opposing surface thin film is formed on an opposing surface.

FIG. 27 is cross-sectional views showing a state (left view) in which opposing through holes are formed in the another semiconductor chip shown in FIG. 26, and a state (right view) in which copper is filled into the through holes to form opposing through electrodes.

FIG. 28 is a cross-sectional view of a wafer to which the another semiconductor chip is to be laminated and connected, showing a state in which a surface thin film and through electrodes are formed.

FIG. 29 is a view illustrating a configuration of an electronic component manufacturing system of another embodiment.

### EMBODIMENTS FOR IMPLEMENTING INVENTION

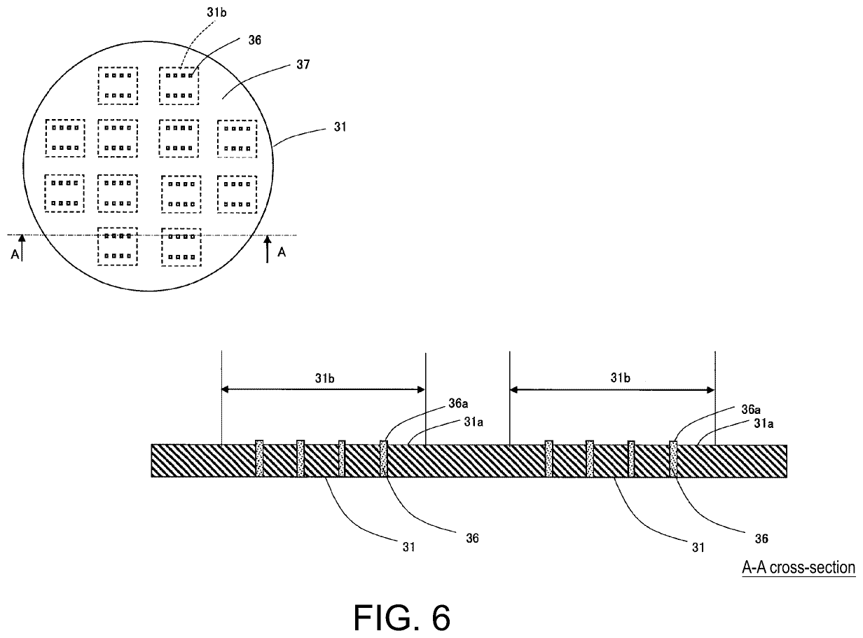

Hereinafter, an alignment method and a bonding method of the embodiment will be described with reference to the drawings. In the following description, an alignment method and a bonding method of a semiconductor chip 32 with respect to a wafer 31 when laminating and bonding the semiconductor chip 32 shown in FIG. 2 onto the wafer 31, which is a plate-shaped electronic component shown in FIG. 6, will be described. In the following description, the surface of the wafer 31 on which the semiconductor chip 32 is laminated will be referred to as a surface 31a, and the surface of the semiconductor chip 32 that is opposed to and overlapped with the surface 31a will be referred to as an opposing surface 32a.

As shown in FIG. 6, the wafer 31 is formed with multiple electrodes 36 having tip surfaces 36a protruding from the surface 31a. In addition, as shown in FIG. 2, the semiconductor chip 32 is formed with multiple opposing electrodes 33 that have tip surfaces 33a protruding from the opposing surface 32a and are disposed at the same pitch as the electrodes 36 of the wafer 31. Upon positioning the semiconductor chip 32 above a chip mounting region 31b (see FIG. 6) of the wafer 31, each opposing electrode 33 is opposed to each electrode 36 of the wafer 31.

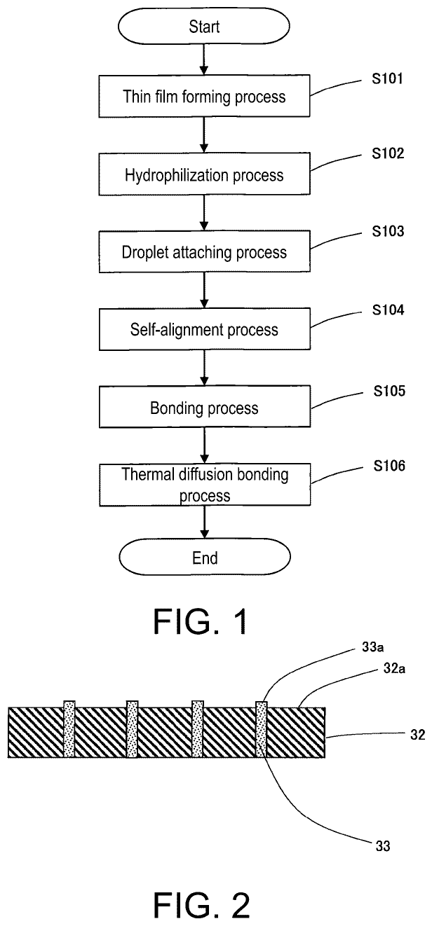

The alignment method of the embodiment includes a thin film forming process shown in step S101 of FIG. 1, a hydrophilization process shown in step S102 of FIG. 1, a droplet attaching process shown in step S103 of FIG. 1, and a self-alignment process shown in step S104 of FIG. 1. In addition, the bonding method of the embodiment includes a bonding process shown in step S105 of FIG. 1 and a thermal diffusion bonding process shown in step S106 of FIG. 1, in addition to the thin film forming process (S101), the hydrophilization process (S102), the droplet attaching process (S103), and the self-alignment process (S104).

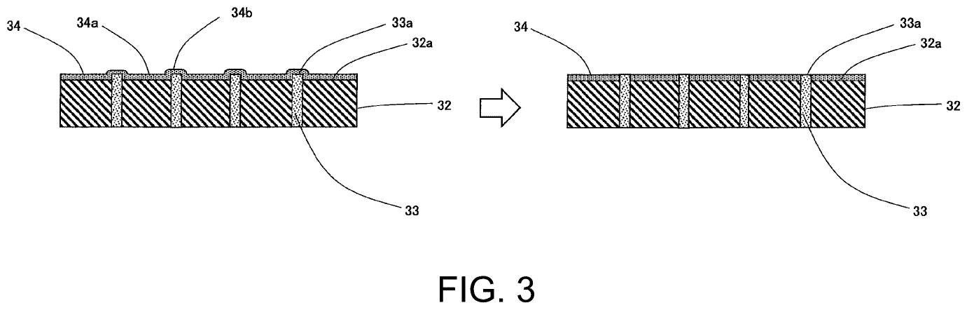

First, the thin film forming process will be described. The thin film forming process is a process of forming an opposing surface thin film 34 on the opposing surface 32a of the semiconductor chip 32, and forming a surface thin film 37 on the surface 31a of the wafer 31. With reference to FIG. 3, the case of forming an opposing surface thin film 34 on the opposing surface 32a of the semiconductor chip 32 will be described. As shown in the left view of FIG. 3, titanium oxide (TiO₂), which is a photoexcited hydrophilization reactant, is coated on the opposing surface 32a of the semiconductor chip 32. The coating of titanium oxide is performed such that the thickness of a thin film 34a formed is substantially the same as the protruding height of the opposing electrodes 33 from the opposing surface 32a. At this time, a thin film 34b of titanium oxide is also formed on the tip surface 33a of the opposing electrode 33.

After forming the thin films 34a and 34b on the opposing surface 32a, as shown in the right view of FIG. 3, the region not including the tip surfaces 33a of the opposing electrodes 33 is masked, and the thin films 34b formed on the tip surfaces 33a of the opposing electrodes 33 are removed by etching. As described above, since the thickness of the thin film 34a formed on the opposing surface 32a is substantially the same as the protruding height of the opposing electrode 33 from the opposing surface 32a, upon removing the thin films 34b formed on the tip surfaces 33a by etching, an opposing surface thin film 34 formed in the region not including the electrodes 36 can be obtained. The height of the upper surface of the opposing surface thin film 34 becomes the same height as the height of the tip surface 33a of the opposing electrode 33. In this manner, the thin film forming process coats titanium oxide (TiO₂) on the opposing surface 32a of the semiconductor chip 32 to form an opposing surface thin film 34 with a thickness the same as the protruding height of the opposing electrode 33 in the region of the opposing surface 32a that does not include the opposing electrodes 33.

In the case of forming a surface thin film 37 on the surface 31a of the wafer 31 shown in FIG. 6, similar to the above, titanium oxide (TiO₂) is coated on the surface 31a to become substantially the same as the protruding height of the electrode 36 from the surface 31a, and the thin film of titanium oxide (TiO₂) formed on the tip surfaces 36a of the electrodes 36 is removed by etching. In this manner, in the thin film forming process, titanium oxide (TiO₂) is coated on the surface 31a of the wafer 31 to form a surface thin film 37 with a thickness the same as the protruding height of the electrode 36 in the region of the surface 31a that does not include each electrode 36.

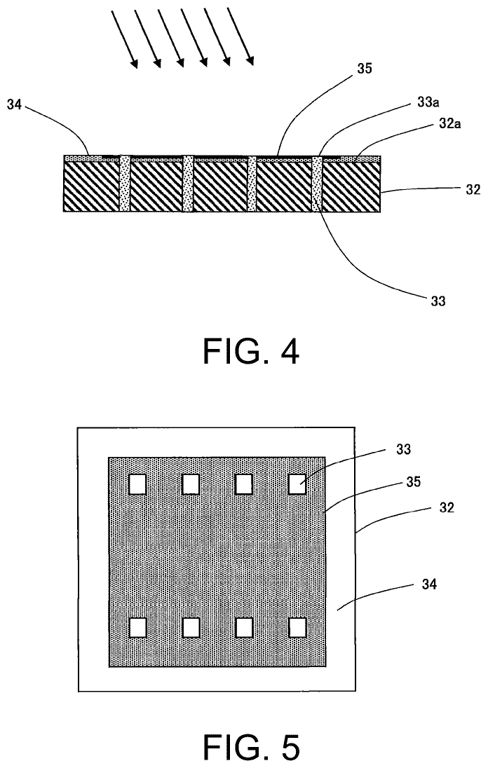

Next, the hydrophilization process will be described. The hydrophilization process is a process of irradiating ultraviolet light onto the surface of the opposing surface thin film 34 formed on the opposing surface 32a of the semiconductor chip 32 as indicated by arrows in FIG. 4 to hydrophilize titanium oxide (TiO₂), which is a photoexcited hydrophilization reactant. As shown in FIG. 5, the region to be irradiated with ultraviolet light and hydrophilized is not the entire opposing surface thin film 34, but is a chip hydrophilization region 35, which is a part of the opposing surface thin film 34 including the surroundings of each opposing electrode 33 of the semiconductor chip 32. The external shape of the chip hydrophilization region 35 is smaller than the external shape of the semiconductor chip 32 and is in a shape similar to the semiconductor chip 32.

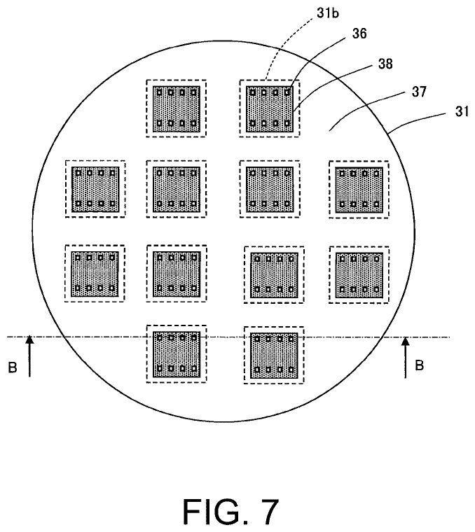

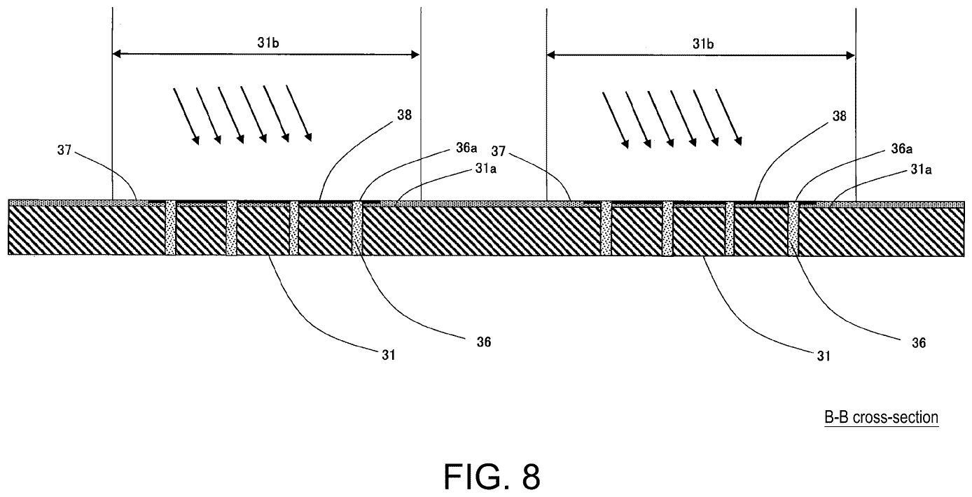

In the hydrophilization process, as indicated by arrows in FIG. 8, ultraviolet light is irradiated onto the surface thin film 37 formed on the surface 31a of the wafer 31 to hydrophilize titanium oxide (TiO₂). As shown in FIG. 7, the region to be hydrophilized is a hydrophilization region 38, which is a part of the surface thin film 37 on the inner side of the chip mounting region 31b. The chip mounting region 31b has the same shape as the external shape of the semiconductor chip 32, and the shape of the hydrophilization region 38 is a similar shape that is smaller than the shape of the chip mounting region 31b. In the alignment method and the bonding method of this embodiment, the hydrophilization region 38 of the wafer 31 and the chip hydrophilization region 35 of the semiconductor chip 32 hydrophilized in the hydrophilization process are regions with the same external shape, and upon positioning the semiconductor chip 32 above the chip mounting region 31b of the wafer 31, the chip hydrophilization region 35 is opposed to the hydrophilization region 38 of the wafer 31.

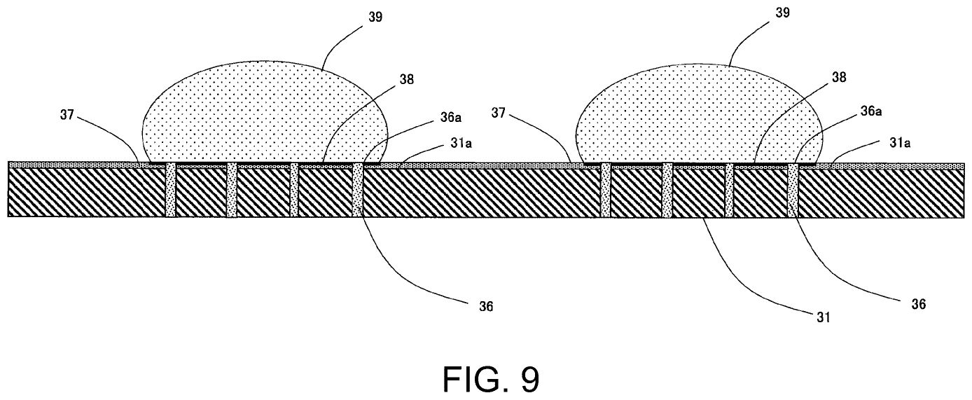

Next, the droplet attaching process will be described. As shown in FIG. 9, the droplet attaching process is a process of attaching, for example, hydrogen water to the upper surface of the hydrophilized hydrophilization region 38 of the wafer 31. Hydrogen water refers to water in which hydrogen gas is dissolved. The hydrogen water attached onto the hydrophilization region 38 spreads over the entire hydrophilization region 38 having hydrophilicity, but does not spread to the surface thin film 37, which is not hydrophilized, on the outer side of the hydrophilization region 38. Thus, the hydrogen water rises from the outer edge of the hydrophilization region 38 and forms a hemispherically raised droplet 39. In the droplet attaching process, droplets 39 of the hydrogen water are attached to the respective upper surfaces of multiple hydrophilization regions 38 shown in FIG. 7 (see FIG. 9).

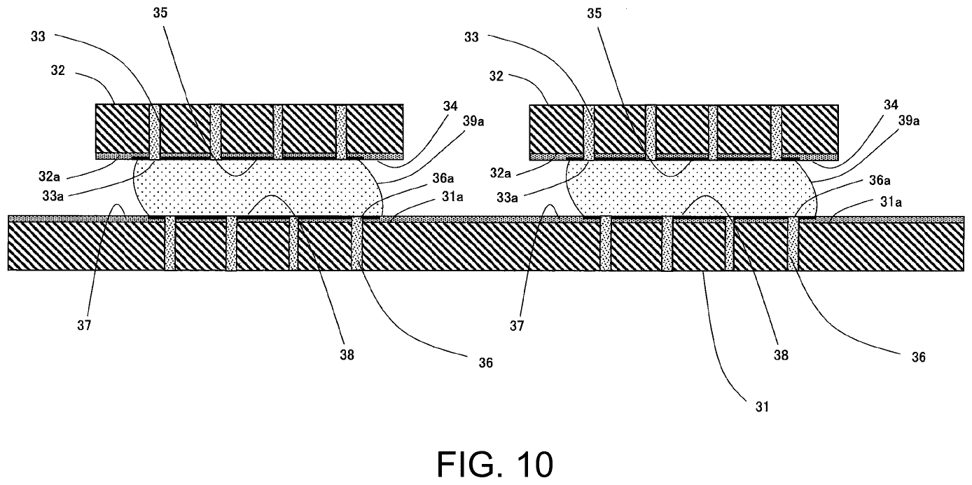

Next, the self-alignment process will be described. As shown in FIG. 10, the self-alignment process is a process of loading the chip hydrophilization region 35 of the semiconductor chip 32 onto the droplet 39, and causing the chip hydrophilization region 35 of the semiconductor chip 32 to self-align with respect to the hydrophilization region 38 of the wafer 31 by the surface tension of the droplet 39.

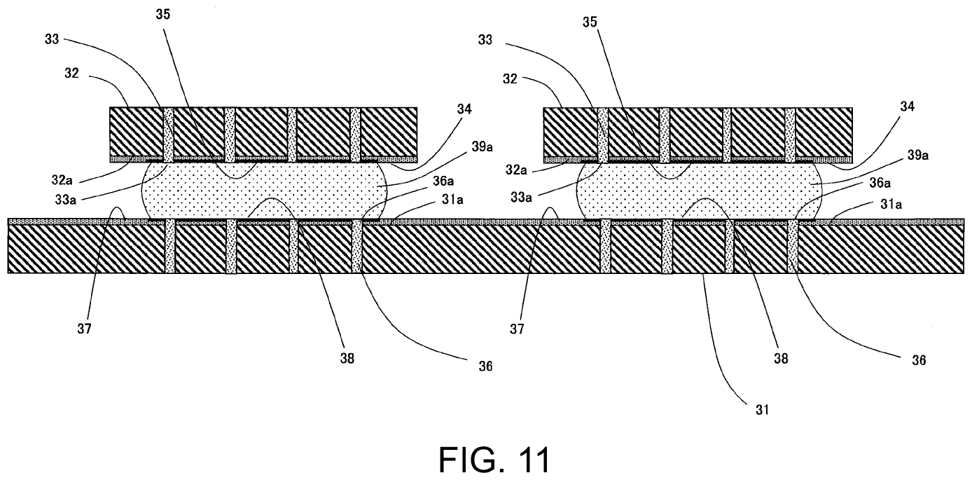

As shown in FIG. 10, the semiconductor chip 32 is inverted upside down such that the chip hydrophilization region 35 of the semiconductor chip 32 is opposed to the wafer 31. Then, the semiconductor chip 32 is aligned with the chip mounting region 31b of the wafer 31 to load the semiconductor chip 32 onto the droplet 39. The droplet 39 in contact with the chip hydrophilization region 35 spreads over the entire chip hydrophilization region 35, but does not spread to the outer side of the chip hydrophilization region 35. Thus, the droplet 39 forms a liquid column 39a in the form of a column having a lower side partitioned by the outer edge of the hydrophilization region 38, having an upper side partitioned by the outer edge of the chip hydrophilization region 35, and having a lateral surface connecting the outer edge of the hydrophilization region 38 and the outer edge of the chip hydrophilization region 35 and bulging outward by surface tension. The liquid column 39a supports the semiconductor chip 32. As described above, since the hydrophilization region 38 of the wafer 31 and the chip hydrophilization region 35 of the semiconductor chip 32 are regions with the same external shape, as shown in FIG. 11, the semiconductor chip 32 is self-aligned by the surface tension of the liquid column 39a such that the outer edge of the hydrophilization region 38 of the wafer 31 on the lower side and the outer edge of the chip hydrophilization region 35 of the semiconductor chip 32 on the upper side are at the same position.

Then, as shown in FIG. 11, with the chip hydrophilization region 35 of the semiconductor chip 32 self-aligned with respect to the hydrophilization region 38 of the wafer 31, positions of each electrode 36 of the wafer 31 and each opposing electrode 33 of the semiconductor chip 32 align with each other.

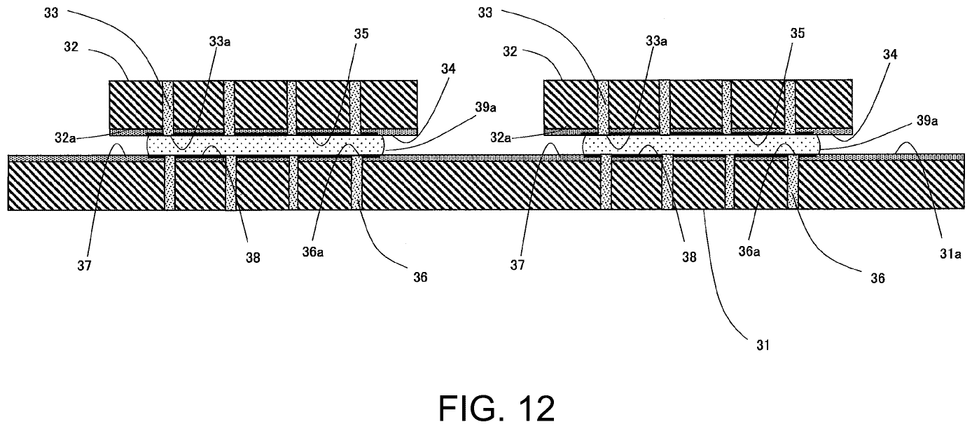

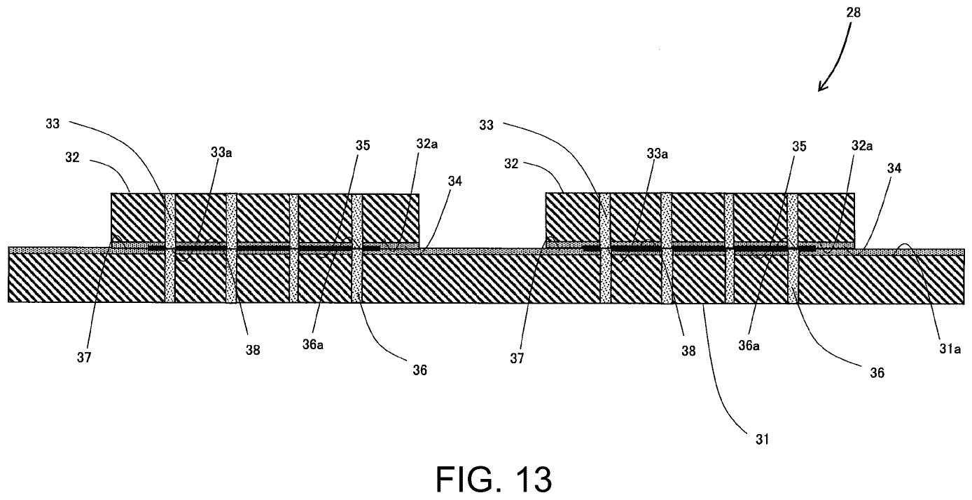

Next, the bonding process and the thermal diffusion bonding process will be described with reference to FIG. 12 to FIG. 13. The bonding process is a process of bringing the chip hydrophilization region 35 of the opposing surface thin film 34 of the semiconductor chip 32 into contact with the hydrophilization region 38 of the surface thin film 37 to hydrophilically bond the hydrophilization region 38 of the surface thin film 37 and the chip hydrophilization region 35 of the opposing surface thin film 34. The thermal diffusion bonding process is a process of heating a bonding body 28 (see FIG. 13) of the wafer 31 and the semiconductor chips 32 bonded in the hydrophilization bonding process to bond, by thermal diffusion, each tip surface 36a of each electrode 36 and each tip surface 33a of each opposing electrode 33 in contact with each other.

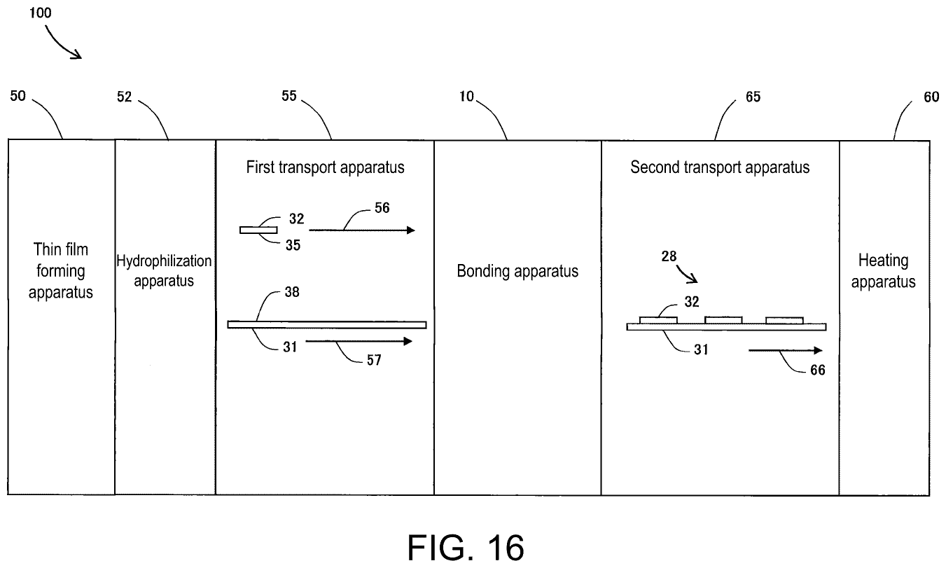

As shown in FIG. 12, upon pressing the semiconductor chip 32 downward, the hydrogen water constituting the liquid column 39a flows out from the outer surface, and the height of the liquid column 39a gradually decreases. Then, the chip hydrophilization region 35 of the semiconductor chip 32 is brought into contact with the hydrophilization region 38 of the wafer 31, and further, upon pressing the chip hydrophilization region 35 against the hydrophilization region 38, the chip hydrophilization region 35 and the hydrophilization region 38 are bonded by hydrophilic bonding, and the bonding body 28 is formed. As described above, the upper surface of the opposing surface thin film 34 formed with the chip hydrophilization region 35 and the tip surface 33a of the opposing electrode 33 are flush with each other, and the upper surface of the surface thin film 37 formed with the hydrophilization region 38 and the tip surface 36a of the electrode 36 are flush with each other. Thus, with the chip hydrophilization region 35 and the hydrophilization region 38 coming into contact with each other, the tip surface 33a of the opposing electrode 33 and the tip surface 36a of the electrode 36 also come into contact with each other. Then, upon heating the bonding body 28 in a heating apparatus 60 (see FIG. 16), each tip surface 36a of each electrode 36 and each tip surface 33a of each opposing electrode 33 in contact with each other are bonded by thermal diffusion bonding, and a semiconductor device is formed.

As described above, since the alignment method of the embodiment self-aligns the position of the chip hydrophilization region 35 of the semiconductor chip 32 with respect to the hydrophilization region 38 of the wafer 31 by the surface tension of the liquid column 39a, the wafer 31 and the semiconductor chip 32 can be aligned with high accuracy.

In addition, since the bonding method of the embodiment self-aligns the position of the chip hydrophilization region 35 of the semiconductor chip 32 with respect to the hydrophilization region 38 of the wafer 31 by the surface tension of the liquid column 39a, and bonds the wafer 31 and the semiconductor chip 32 in this state, the wafer 31 and the semiconductor chip 32 can be bonded with high alignment accuracy.

Furthermore, since the bonding method of the embodiment bonds the hydrophilization region 38 of the surface thin film 37 of the wafer 31 and the tip surface 36a of the electrode 36, which are formed at the same height, respectively to the chip hydrophilization region 35 of the opposing surface thin film 34 of the semiconductor chip 32 and the tip surface 33a of the opposing electrode 33, which are formed at the same height, by hydrophilic bonding and thermal diffusion bonding, no gap is formed between the wafer 31 and the semiconductor chip 32 after bonding, and it is not required to fill a gap with an adhesive or the like. Thus, a semiconductor device with high bonding quality can be manufactured by a simple method.

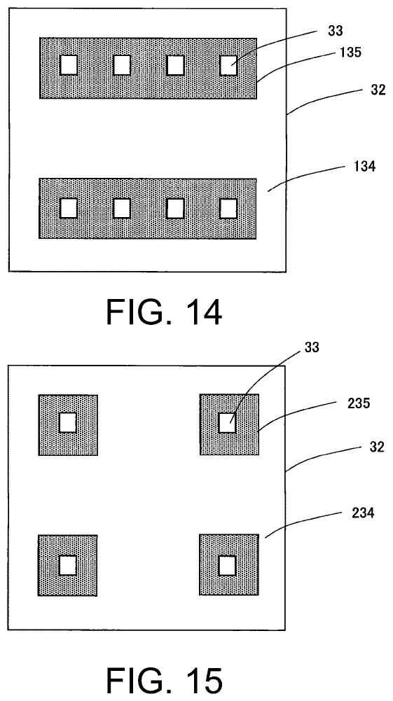

In the above description, the chip hydrophilization region 35 of the semiconductor chip 32 has been described as having an external shape in a shape similar to the external shape of the semiconductor chip 32. However, as long as it is a region including the surroundings of each opposing electrode 33, for example, as shown in FIG. 14, multiple spots of an opposing surface thin film 134 may also be hydrophilized to provide multiple chip hydrophilization regions 135. In addition, as shown in FIG. 15, chip hydrophilization regions 235 may also be provided respectively on the opposing surface thin film 234 around each opposing electrode 33. In that case, the shape of the hydrophilization region 38 of the wafer 31 may be configured to be the same shape as the chip hydrophilization regions 135 and 235 described above.

In addition, in the above description, titanium oxide (TiO₂) has been described to be used as the photoexcited hydrophilization reactant, but the embodiment is not limited thereto. For example, one of tungsten trioxide, silver bromide, silver chloride, silicon dioxide (SiO₂), nitrogen-doped silicon carbide (SiCN), silicon nitride (SiN), or carbon-doped silicon monoxide (SiOC) may also be used.

In addition, in the above description, the droplet 39 has been described as being formed using hydrogen water, but the embodiment is not limited thereto, and one of ozone water, carbon water, alkaline electrolytic water, or fine bubble water may also be used.

In addition, in the above description, the opposing surface thin film 34 and the surface thin film 37 have been described as being hydrophilized using ultraviolet light, but the embodiment is not limited thereto, and hydrophilization may also be performed using visible light.

Next, with reference to FIG. 16 to FIG. 18, an electronic component manufacturing system 100 that executes the alignment method and the bonding method described above to manufacture a semiconductor device will be described.

As shown in FIG. 16, the electronic component manufacturing system 100 includes a thin film forming apparatus 50, a hydrophilization apparatus 52, a bonding apparatus 10, a heating apparatus 60, a first transport apparatus 55, and a second transport apparatus 65.

The thin film forming apparatus 50 includes therein a coating apparatus that performs coating of titanium oxide (TiO₂), an etching apparatus, and a transport apparatus (not shown).

The thin film forming apparatus 50 coats titanium oxide (TiO₂) onto the opposing surface 32a of the semiconductor chip 32 shown in FIG. 2, then removes the thin films 34b formed on the tip surfaces 33a of the opposing electrodes 33 to form an opposing surface thin film 34, and coats titanium oxide (TiO₂) onto the surface 31a of the wafer 31 shown in FIG. 6, and then removes the thin film formed on the tip surfaces 36a of the electrodes 36 to form a surface thin film 37. As described above with reference to FIG. 2 and FIG. 3, the thin film forming apparatus 50 forms the opposing surface thin film 34 with a thickness the same as the protruding height of the opposing electrode 33 in the region of the opposing surface 32a that does not include the opposing electrodes 33, and forms the surface thin film 37 with a thickness the same as the protruding height of the electrode 36 in the region of the surface 31a that does not include each electrode 36. Then, the semiconductor chips 32 formed with the opposing surface thin films 34 and the wafer 31 formed with the surface thin film 37 are supplied to the hydrophilization apparatus 52.

The hydrophilization apparatus 52 includes therein an ultraviolet irradiation apparatus. The hydrophilization apparatus 52 irradiates ultraviolet light onto the opposing surface thin film 34 of the semiconductor chip 32 to form the chip hydrophilization region 35. In addition, the hydrophilization apparatus 52 irradiates ultraviolet light onto the surface thin film 37 of the wafer 31 to form the hydrophilization region 38.

As indicated by arrows 56 and 57 in FIG. 16, the first transport apparatus 55 transports the semiconductor chips 32 and the wafer 31, which have been hydrophilized by the hydrophilization apparatus 52, to the bonding apparatus 10.

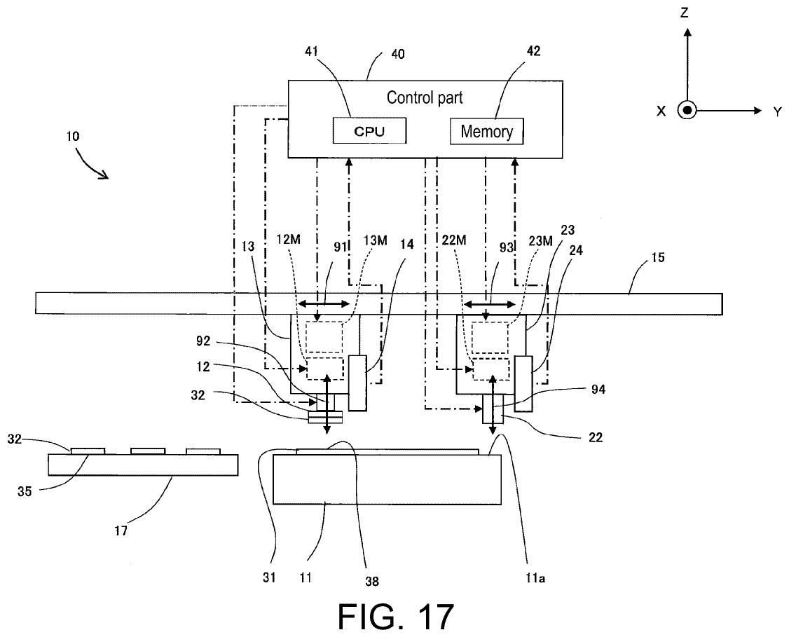

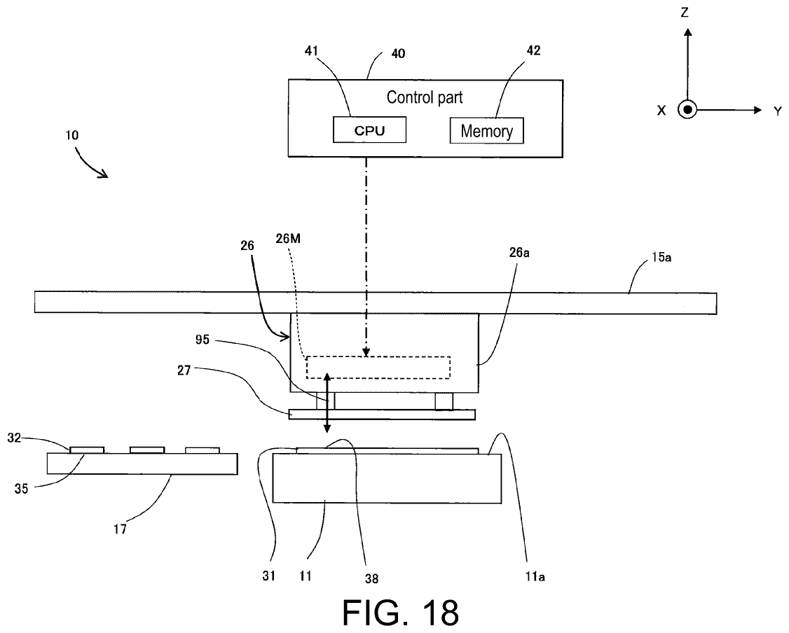

The bonding apparatus 10 is an apparatus that bonds the semiconductor chips 32 to the upper surface of the wafer 31 supplied from the hydrophilization apparatus 52 by the first transport apparatus 55 to form a bonding body 28. Details of the bonding apparatus 10 will be described later with reference to FIG. 17 and FIG. 18.

As indicated by an arrow 66 in FIG. 16, the second transport apparatus 65 transports the bonding body 28 bonded by the bonding apparatus 10 to the heating apparatus 60.

The heating apparatus 60 heats the bonding body 28 supplied from the bonding apparatus 10 to bond, by thermal diffusion, each tip surface 36a of each electrode 36 and each tip surface 33a of each opposing electrode 33 in contact with each other.

Next, the configuration of the bonding apparatus 10 will be described with reference to FIG. 17 and FIG. 18. As shown in FIG. 17, the bonding apparatus 10 includes a stage 11, a collet 12, a bonding head 13, a guide rail 15, a first camera 14, a loading table 17, a dispenser 22, a dispenser head 23, a second camera 24, a pressing device 26 shown in FIG. 18, and a control part 40 shown in FIG. 17 and FIG. 18. In the following description, the direction in which the guide rail 15 extends will be referred to as a Y-direction, the direction orthogonal to the Y-direction in the horizontal plane will be referred to as an X-direction, and the up-down direction will be referred to as a Z-direction. In addition, the side of the loading table 17 will be described as the negative side in the Y-direction, the side of the stage 11 will be described as the positive side in the Y-direction, the close side of the paper in FIG. 1 will be described as the positive side in the X-direction, the far side of the paper will be described as the negative side in the X-direction, the upward direction will be described as the positive side in the Z-direction, and the downward direction will be described as the negative side in the Z-direction.

The stage 11 adsorbs and fixes the wafer 31 on the upper surface. The collet 12 is connected to the lower end of the bonding head 13, adsorbs the semiconductor chip 32 at the tip to hold the semiconductor chip 32, and releases the semiconductor chip 32.

The bonding head 13 includes a Y-direction driving motor 13M therein, and is guided by the guide rail 15 to move in the Y-direction as indicated by an arrow 91 in FIG. 17. In addition, the bonding head 13 includes therein a Z-direction driving motor 12M that moves the collet 12 in the Z-direction as indicated by an arrow 92 in FIG. 17. In addition, the guide rail 15 moves in the X-direction by an X-direction driving apparatus (not shown). Thus, the bonding head 13 and the X-direction driving apparatus (not shown) move the collet 12 in the XY-direction, which is a direction along an adsorption surface 11a of the stage 11, and in the Z-direction, which is a direction contacting and separating from the adsorption surface 11a.

The first camera 14 is attached to the bonding head 13 to acquire images of the wafer 31 adsorbed on the stage 11 or the semiconductor chip 32 loaded on the loading table 17.

The loading table 17 is a table on which the semiconductor chip 32 with the chip hydrophilization region 35 hydrophilized by the hydrophilization apparatus 52 is temporarily loaded. The loading table 17 may be configured to be capable of loading the semiconductor chip 32 on the upper surface in a non-contact manner, for example, by ultrasonic vibration or air pressure.

The dispenser 22 is connected to the lower end of the dispenser head 23 and drops hydrogen water from the tip.

Similar to the bonding head 13, the dispenser head 23 includes a Y-direction driving motor 23M therein, and is guided by the guide rail 15 to move in the Y-direction as indicated by an arrow 93 in FIG. 17. In addition, the dispenser head 23 includes therein a Z-direction driving motor 22M that moves the dispenser 22 in the Z-direction as indicated by an arrow 94 in FIG. 17. Similar to the bonding head 13, the dispenser head 23 and the X-direction driving apparatus (not shown) move the dispenser 22 in the XY-direction, which is a direction along the adsorption surface 11a of the stage 11, and in the Z-direction, which is a direction contacting and separating from the adsorption surface 11a.

The second camera 24 is attached to the dispenser head 23 to acquire images of the wafer 31 adsorbed on the stage 11 or the semiconductor chip 32 attached on the wafer 31.

As shown in FIG. 18, the pressing device 26 is configured with a main body 26a attached to an upper frame 15a of the bonding apparatus 10, and a pressing plate 27 attached to the lower side of the main body 26a. The main body 26a includes therein a Z-direction driving motor 26M that drives the pressing plate 27 in the Z-direction as indicated by an arrow 95 in FIG. 18.

The control part 40 is a computer that includes a CPU 41, which is a processor performing information processing, and a memory 42 storing operation programs and control data. The image data acquired by the first camera 14 and the second camera 24 is inputted to the control part 40. The control part 40 detects the position of the chip mounting region 31b of the wafer 31 or the position of the semiconductor chip 32, by performing image analysis on the inputted image data. In addition, the Z-direction driving motor 12M attached inside the bonding head 13 detects the Z-direction position of the collet 12 to output to the control part 40. Similarly, the Z-direction driving motor 22M attached inside the dispenser head 23 detects the Z-direction position of the dispenser 22 to output to the control part 40.

The Y-direction driving motor 13M and the Z-direction driving motor 12M of the bonding head 13, the Y-direction driving motor 23M and the Z-direction driving motor 22M of the dispenser head 23, the X-direction driving apparatus, the collet 12, the dispenser 22, and the Z-direction driving motor 26M of the pressing device 26 operate according to commands of the control part 40. The Y-direction driving motor 13M and the Z-direction driving motor 12M of the bonding head 13 and the X-direction driving apparatus adjust the XYZ position of the collet 12 based on commands from the control part 40. In addition, the collet 12 performs adsorption holding and releasing of the semiconductor chip 32 according to commands from the control part 40. Similarly, the Y-direction driving motor 23M and the Z-direction driving motor 22M of the dispenser head 23 and the X-direction driving apparatus adjust the XYZ position of the dispenser 22 based on commands from the control part 40. In addition, the dispenser 22 performs dropping of hydrogen water according to commands from the control part 40. The Z-direction driving motor 26M of the pressing device 26 adjusts the Z-direction position of the pressing plate 27 based on commands of the control part 40.

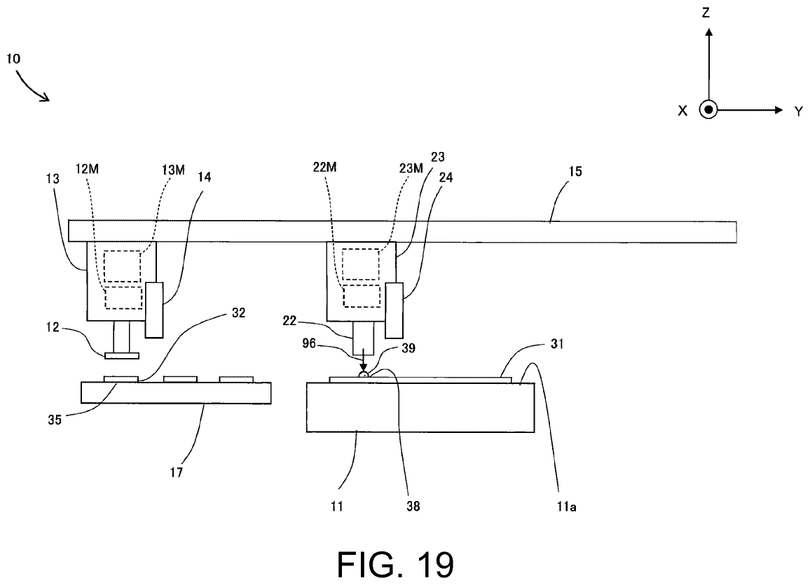

Next, the operation of bonding the semiconductor chip 32 onto the wafer 31 by the electronic component manufacturing system 100 will be described with reference to FIG. 19 to FIG. 24.

As shown in FIG. 19, the semiconductor chip 32 (see FIG. 4) with the chip hydrophilization region 35 hydrophilized by the hydrophilization apparatus 52 is loaded on the loading table 17 such that the chip hydrophilization region 35 is on the lower side. In addition, the wafer 31 (see FIG. 7 and FIG. 8) with the hydrophilization region 38 hydrophilized is adsorbed and fixed on the stage 11. The control part 40 drives the Y-direction driving motor 13M of the bonding head 13 to move the position of the collet 12 above the loading table 17.

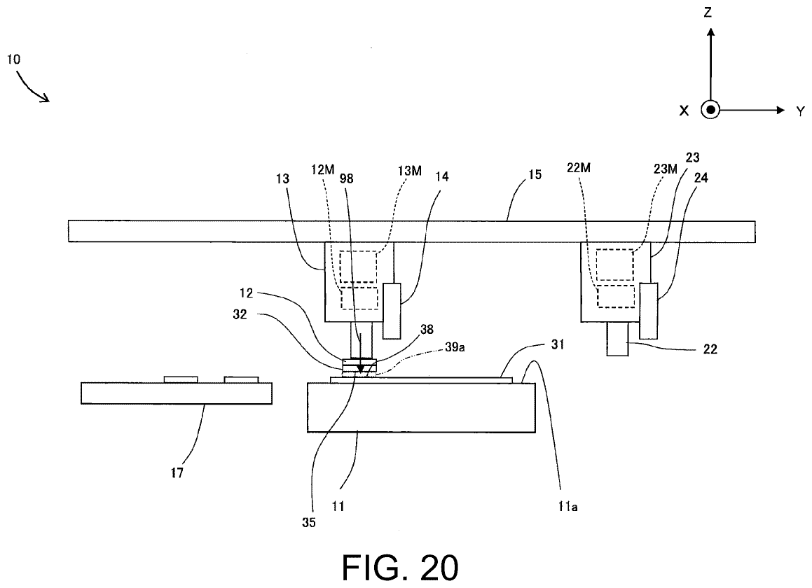

The control part 40 drives the Y-direction driving motor 23M of the dispenser head 23 to move the position of the dispenser 22 above the hydrophilization region 38 of the wafer 31, and then lowers the tip to a specific height. Then, the control part 40 drives the dispenser 22 to drop hydrogen water onto the hydrophilization region 38 as indicated by an arrow 96 in FIG. 19. The control part 40 similarly drops hydrogen water onto each hydrophilization region 38 of the wafer 31. The dropped hydrogen water forms a droplet 39 as shown in FIG. 9 on the hydrophilization region 38 of the wafer 31. After completing the dropping of hydrogen water onto each hydrophilization region 38, the control part 40 drives the Y-direction driving motor 23M to move the dispenser head 23 outside the stage 11 as shown in FIG. 20.

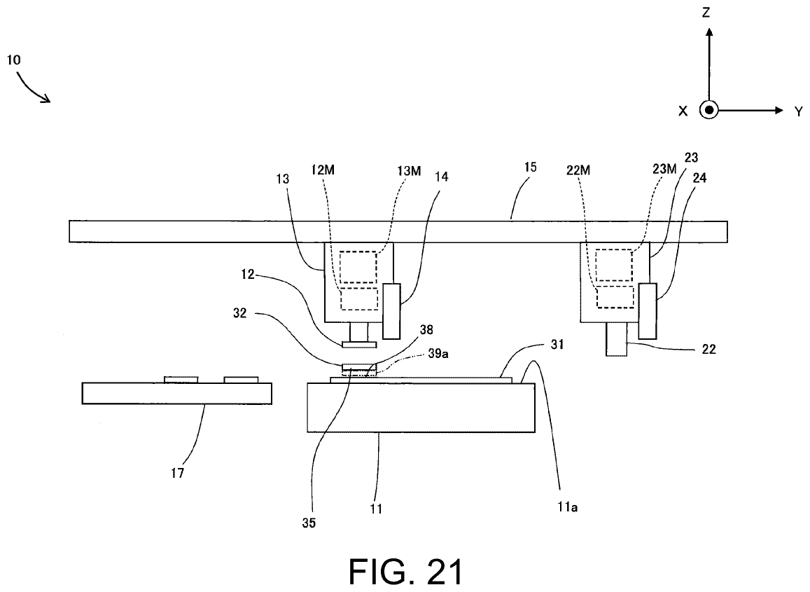

The control part 40 drives the Z-direction driving motor 12M of the bonding head 13 shown in FIG. 19 to lower the collet 12 onto the semiconductor chip 32, holds the semiconductor chip 32 with the collet 12, and raises the collet 12 with the Z-direction driving motor 12M to pick up the semiconductor chip 32. Then, the Y-direction driving motor 13M is driven to move the semiconductor chip 32 to above the chip mounting region 31b (see FIG. 7 and FIG. 8) of the wafer 31 as shown in FIG. 20. Then, the control part 40 drives the Z-direction driving motor 12M to lower the collet 12 to above the droplet 39 of the hydrophilization region 38 of the wafer 31 as indicated by an arrow 98 in FIG. 20, and as shown in FIG. 21, releases the hold on the semiconductor chip 32 to load the semiconductor chip 32 onto the droplet 39. Then, as described with reference to FIG. 10 and FIG. 11, the semiconductor chip 32 is self-aligned by the surface tension of the liquid column 39a such that the outer edge of the hydrophilization region 38 of the wafer 31 on the lower side and the outer edge of the chip hydrophilization region 35 of the semiconductor chip 32 on the upper side are at the same position.

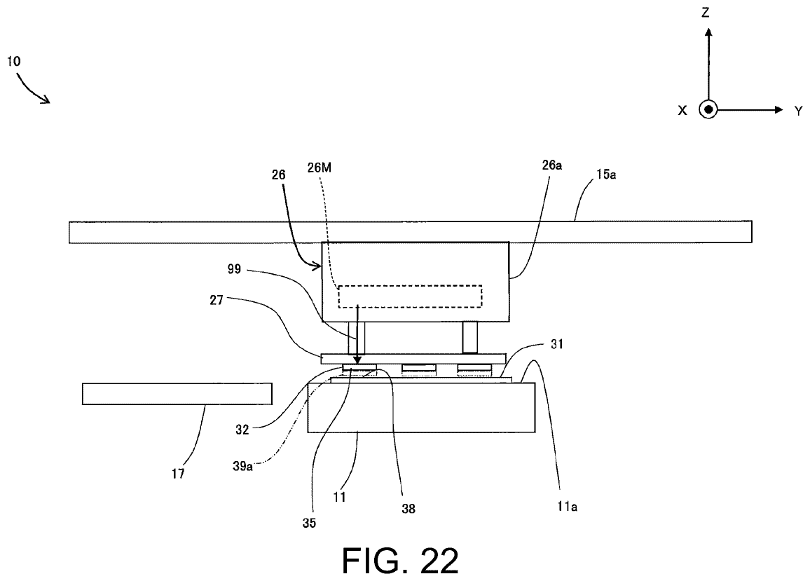

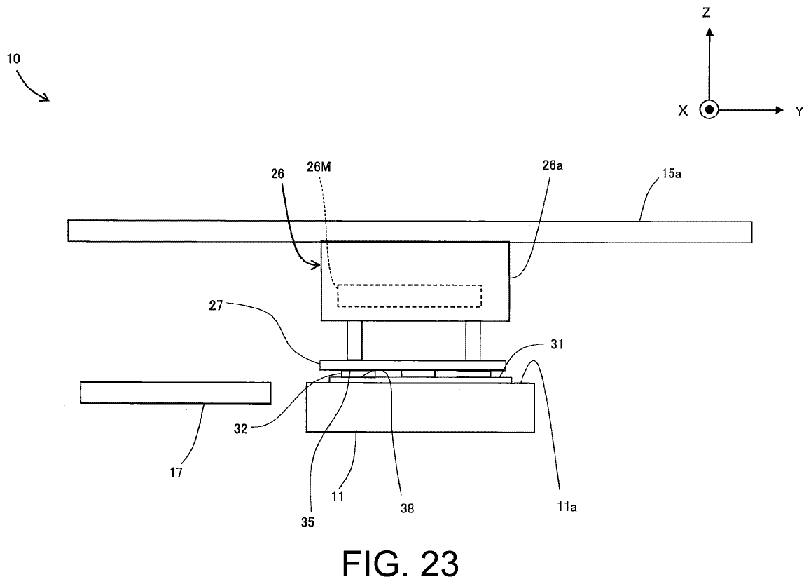

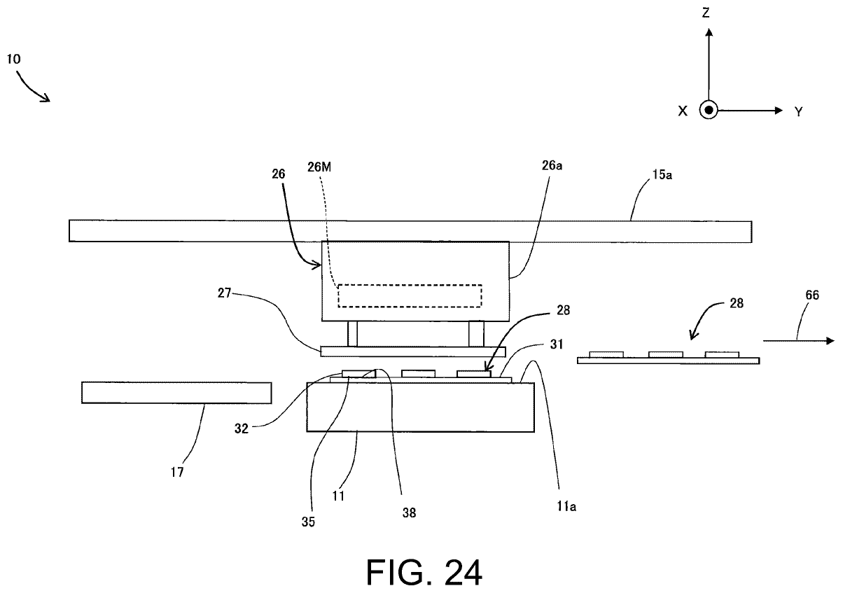

Next, as shown in FIG. 22, the control part 40 moves the pressing device 26 above the stage 11, drives the Z-direction driving motor 26M to lower the pressing plate 27 toward the semiconductor chip 32 as indicated by an arrow 99 in FIG. 22, and as shown in FIG. 23, simultaneously presses multiple semiconductor chips 32 against the wafer 31. Accordingly, as described with reference to FIG. 13, the chip hydrophilization region 35 and the hydrophilization region 38 come into contact and are hydrophilically bonded, and a bonding body 28 with the tip surfaces 33a of the opposing electrodes 33 and the tip surfaces 36a of the electrodes 36 in contact with each other is formed. As indicated by an arrow 66 in FIG. 24 and FIG. 16, the formed bonding body 28 is transported into the heating apparatus 60 by the second transport apparatus 65. Then, upon heating the bonding body 28 in the heating apparatus 60 (see FIG. 16), each tip surface 36a of each electrode 36 and each tip surface 33a of each opposing electrode 33 in contact with each other are bonded by thermal diffusion bonding, and a semiconductor device is completed.

Similar to the bonding method described above, since the electronic component manufacturing system 100 of the embodiment described above self-aligns the position of the chip hydrophilization region 35 of the semiconductor chip 32 with respect to the hydrophilization region 38 of the wafer 31 by the surface tension of the liquid column 39a, and bonds the wafer 31 and the semiconductor chip 32 in this state, the wafer 31 and the semiconductor chip 32 can be bonded with high alignment accuracy.

In addition, similar to the bonding method described above, since the electronic component manufacturing system 100 of the embodiment bonds the hydrophilization region 38 of the surface thin film 37 of the wafer 31 and the tip surface 36a of the electrode 36, which are formed at the same height, respectively to the chip hydrophilization region 35 of the opposing surface thin film 34 of the semiconductor chip 32 and the tip surface 33a of the opposing electrode 33, which are formed at the same height, by hydrophilic bonding and thermal diffusion bonding, no gap is formed between the wafer 31 and the semiconductor chip 32 after bonding, and it is not required to fill a gap with an adhesive or the like. Thus, a semiconductor device with high bonding quality can be manufactured.

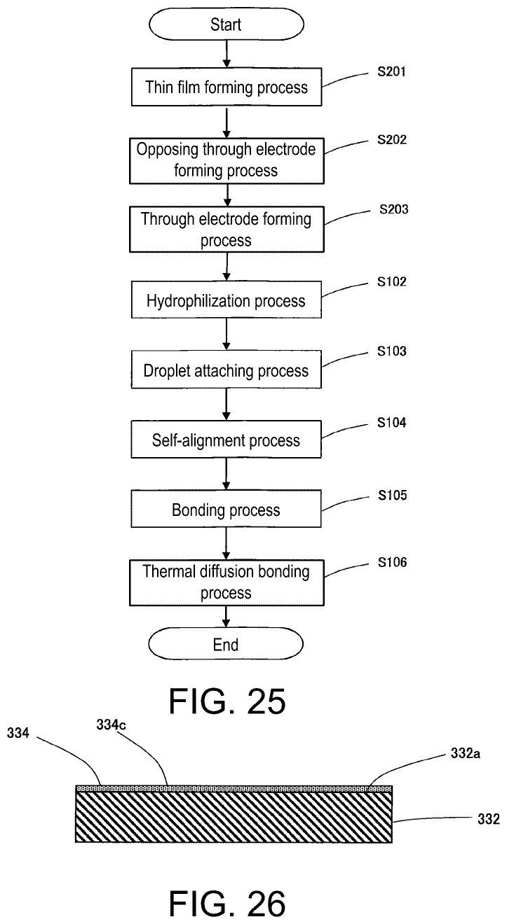

Next, with reference to FIG. 25 to FIG. 28, another bonding method for bonding a semiconductor chip 332 of another structure to a wafer 331 of another structure will be described.

The another bonding method includes a thin film forming process shown in step S201 of FIG. 25, an opposing through electrode forming process shown in step S202 of FIG. 25, a through electrode forming process shown in step S203 of FIG. 25, and a hydrophilization process, a droplet attaching process, a self-alignment process, a bonding process, and a thermal diffusion bonding process shown in steps S102 to S106 of FIG. 25.

As shown in FIG. 26, different from the semiconductor chip 32 described above, the semiconductor chip 332 does not have an opposing electrode 33 with a tip surface 33a protruding from an opposing surface 332a. In addition, the wafer 331 does not have an electrode 36 with a tip surface 36a protruding from a surface 331a, either.

As shown in FIG. 26, the thin film forming process coats titanium oxide (TiO₂), which is a photoexcited hydrophilization reactant, onto the opposing surface 332a of the semiconductor chip 332 to form an opposing surface thin film 334, and coats titanium oxide (TiO₂) onto the surface 331a of the wafer 331 to form a surface thin film 335.

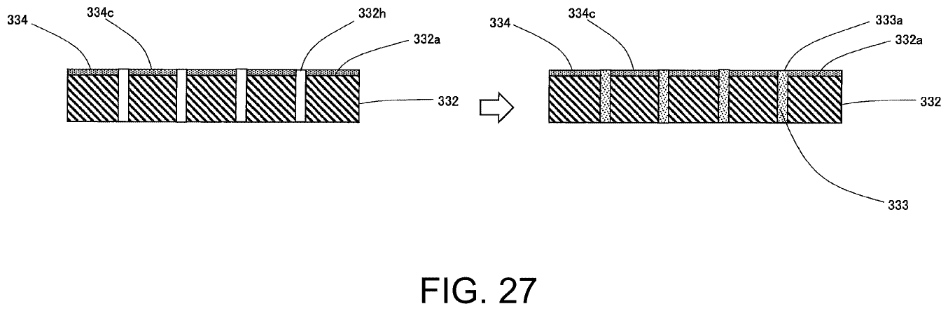

The opposing through electrode forming process is a process of forming, in the semiconductor chip 332 formed with the opposing surface thin film 334, opposing through electrodes 333 that penetrate through the semiconductor chip 332 and the opposing surface thin film 334 in the thickness direction of the semiconductor chip 332. The opposing through electrode forming process includes an etching process of forming, in the semiconductor chip 332 formed with the opposing surface thin film 334, opposing through holes 332h penetrating through the semiconductor chip 332 and the opposing surface thin film 334 in the thickness direction of the semiconductor chip 332 as shown in the left view of FIG. 27, and a metal filling process of filling the formed opposing through holes 332h with a metal such as copper, as shown in the right view of FIG. 27. Upon filling the opposing through holes 332h with the metal, opposing through electrodes 333 as shown in the right view of FIG. 27 are formed. The metal filling process fills the metal such that a tip surface 333a of the opposing through electrode 333 is flush with an upper surface 334c of the opposing surface thin film 334. Thus, the upper surface 334c of the opposing surface thin film 334 and the tip surface 333a of the opposing through electrode 333 are flush with each other.

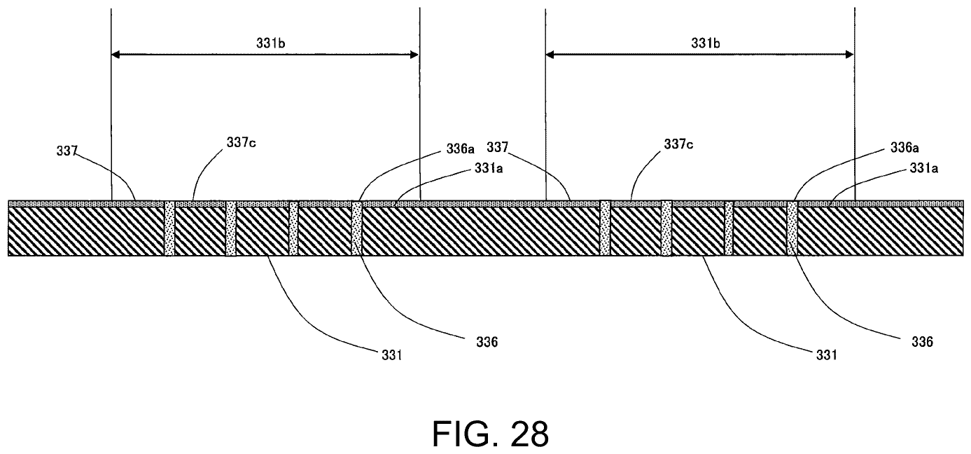

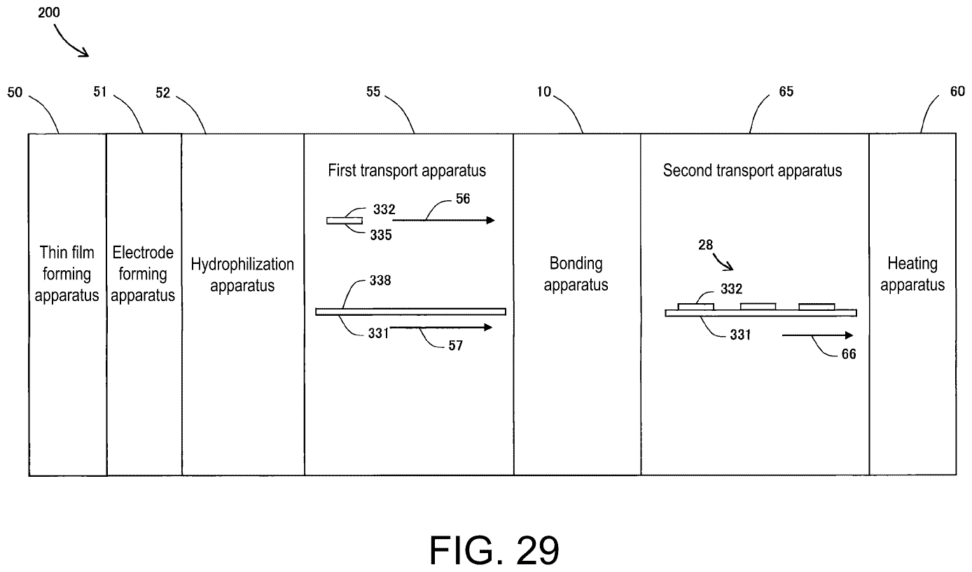

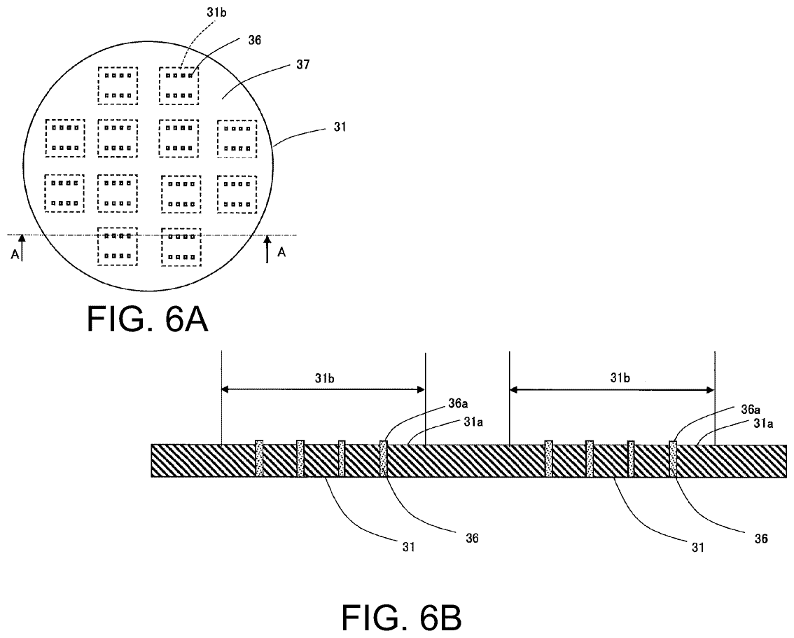

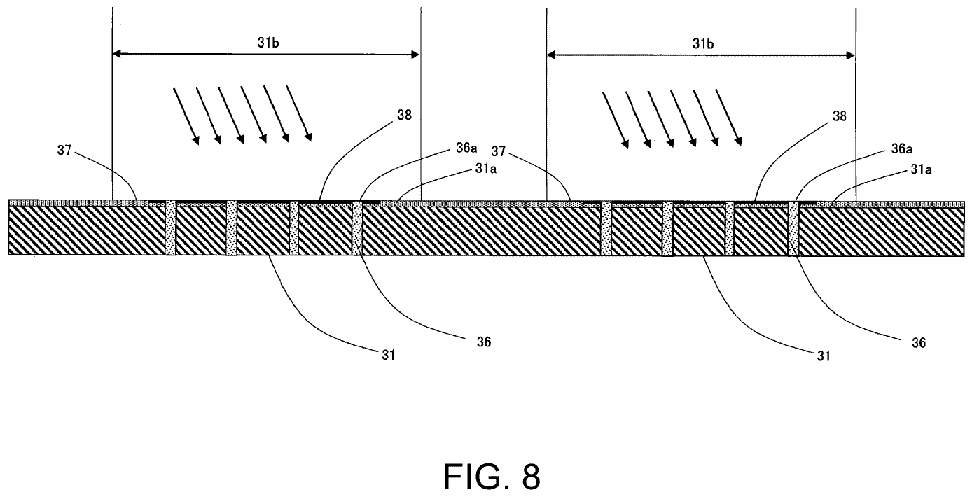

Similarly, the through electrode forming process includes an etching process of forming, in the wafer 31 formed with the surface thin film 337, through holes (not shown) penetrating through the wafer 31 and the surface thin film 337 in the thickness direction of the wafer 331, and a metal filling process of filling the formed through holes with a metal. Upon filling the through holes with the metal, through electrodes 336 as shown in FIG. 28 are formed. The metal filling process fills the metal such that a tip surface 336a of the through electrode 336 is flush with an upper surface 337c of the surface thin film 337. Thus, the upper surface 337c of the surface thin film 337 and the tip surface 336a of the through electrode 336 are flush with each other.

The hydrophilization process, the droplet attaching process, the self-alignment process, the bonding process, and the thermal diffusion bonding process are the same as the bonding method described above with reference to FIG. 1 to FIG. 13, so repeated descriptions thereof will be omitted.

The another bonding method achieves the same actions/effects as the bonding method described above with reference to FIG. 1 to FIG. 13.

Next, an electronic component manufacturing system 200 that executes the another bonding method described above to manufacture a semiconductor device will be described. Components similar to those in the electronic component manufacturing system 100 described above with reference to FIG. 16 to FIG. 24 will be labeled with the same reference signs, and descriptions thereof will be omitted.

The electronic component manufacturing system 200 has the same configuration as the electronic component manufacturing system 100 described above with reference to FIG. 16 to FIG. 24, except that an electrode forming apparatus 51 is included.

The electrode forming apparatus 51 includes therein an etching apparatus (not shown) and a metal filling apparatus (not shown). The etching apparatus forms opposing through holes 332h in the semiconductor chip 332 on which the opposing surface thin film 334 has been formed by the thin film forming apparatus 50. The metal filling apparatus fills the opposing through holes 332h with a metal such as copper to form opposing through electrodes 333. In addition, the etching apparatus forms through holes (not shown) in the wafer 31 on which the surface thin film 337 has been formed by the thin film forming apparatus 50, and the metal filling apparatus fills the through holes with a metal to form through electrodes 336.

The through electrodes 336 of the wafer 331 and the opposing through electrodes 333 of the semiconductor chip 332 are formed with the same pitch. Thus, upon positioning the semiconductor chip 332 above a chip mounting region 331b of the wafer 331, each opposing through electrode 333 of the semiconductor chip 332 is opposed to each through electrode 336 of the wafer 31.

The metal filling apparatus fills the metal such that the tip surface 333a of the opposing through electrode 333 is flush with the upper surface 334b of the opposing surface thin film 334. Thus, the upper surface 334b of the opposing surface thin film 334 and the tip surface 333a of the opposing through electrode 333 are flush with each other. Similarly, the metal filling apparatus fills the metal such that the tip surface 336a of the through electrode 336 is flush with the upper surface 337b of the surface thin film 337. Thus, the upper surface 337c of the surface thin film 337 and the tip surface 336a of the through electrode 336 are flush with each other.

Similar to the electronic component manufacturing system 100 described above, in the electronic component manufacturing system 200, the hydrophilization apparatus 52 forms a chip hydrophilization region 35 on the semiconductor chip 332 and forms a hydrophilization region 38 on the wafer 31, and the semiconductor chip 332 and the wafer 331 are transported to the bonding apparatus 10 by the first transport apparatus 55. The bonding apparatus 10 bonds the semiconductor chips 332 onto the wafer 331 to form a bonding body 28 in the same operation as described above with reference to FIG. 19 to FIG. 24. The bonding body 28 is transported to the heating apparatus 60 by the second transport apparatus 65 and is heated by the heating apparatus 60, and the tip surfaces 336a of the through electrodes 336 and the tip surfaces 333a of the opposing through electrodes 333 are bonded by thermal diffusion to form a semiconductor device.

The electronic component manufacturing system 200 achieves the same actions/effects as the electronic component manufacturing system 100 described above.

In the bonding method and the electronic component manufacturing systems 100 and 200 described above, it has been described that the semiconductor chip 32 and 332 is bonded onto the wafer 31 and 331, but the embodiments are not limited thereto and may also be applied to the case where another semiconductor chip is laminated and bonded onto the semiconductor chip 32 and 332. In addition, the embodiments may also be applied to the case where the semiconductor chip 32 and 332 is laminated and bonded onto a substrate instead of the wafer 31.

### REFERENCE SIGNS LIST

10 bonding apparatus, 11 stage, 11a adsorption surface, 12 collet, 12M, 22M, 26M Z-direction driving motor, 13 bonding head, 13M, 23M Y-direction driving motor, 15 guide rail, 15a upper frame, 17 loading table, 22 dispenser, 23 dispenser head, 26 pressing device, 26a main body, 27 pressing plate, 28 bonding body, 31, 331 wafer, 31a, 331a surface, 31b, 331b chip mounting region, 32, 332 semiconductor chip, 32a, 332a opposing surface, 33 opposing electrode, 33a, 333a, tip surface, 34, 134, 234, 334 opposing surface thin film, 34a, 34b thin film, 35, 135, 235 chip hydrophilization region, 36 electrode, 36a, 336a tip surface, 37, 337 surface thin film, 38 hydrophilization region, 39 droplet, 39a liquid column, 40 control part, 41 CPU, 42 memory, 50 thin film forming apparatus, 51 electrode forming apparatus, 52 hydrophilization apparatus, 55 first transport apparatus, 60 heating apparatus, 65 second transport apparatus, 100, 200 electronic component manufacturing system, 332h opposing through hole, 333 opposing through electrode, 334c, 337c upper surface, 336 through electrode

1. An alignment method, which is an alignment method of a first semiconductor chip in a case of laminating and bonding the first semiconductor chip to a plate-shaped electronic component, the alignment method comprising:
a thin film forming process of coating a photoexcited hydrophilization reactant onto a surface of the electronic component and an opposing surface of the first semiconductor chip that is opposed to the surface, to form a surface thin film and an opposing surface thin film;
a hydrophilization process of irradiating light onto a hydrophilization region, which is a part of the surface thin film, and a chip hydrophilization region of the opposing surface thin film that is opposed to the hydrophilization region, to hydrophilize the hydrophilization region and the chip hydrophilization region;
a droplet attaching process of attaching a droplet to the hydrophilized hydrophilization region of the electronic component; and
a self-alignment process of loading the hydrophilized chip hydrophilization region of the first semiconductor chip onto the droplet, and causing the chip hydrophilization region of the first semiconductor chip to self-align with respect to the hydrophilization region of the electronic component by surface tension of the droplet.

2. The alignment method according to claim 1, wherein
the hydrophilization region and the chip hydrophilization region are regions having a same external shape and smaller than an external shape of the first semiconductor chip.

3. The alignment method according to claim 1, wherein
the photoexcited hydrophilization reactant is selected from any one of titanium oxide, tungsten trioxide, silver bromide, silver chloride, silicon dioxide, nitrogen-doped silicon carbide, silicon nitride, or carbon-doped silicon monoxide,
the droplet is composed of a liquid selected from any one of hydrogen water, ozone water, carbon water, alkaline electrolytic water, or fine bubble water, and
the light is ultraviolet light.

4. The alignment method according to claim 3, wherein
the electronic component is a wafer, a second semiconductor chip different from the first semiconductor chip, or a substrate.

5. A bonding method, which is a bonding method of laminating and bonding a first semiconductor chip to a plate-shaped electronic component, the bonding method comprising:
a thin film forming process of coating a photoexcited hydrophilization reactant onto a surface of the electronic component and an opposing surface of the first semiconductor chip that is opposed to the surface, to form a surface thin film and an opposing surface thin film;
a hydrophilization process of irradiating light onto a hydrophilization region, which is a part of the surface thin film, and a chip hydrophilization region of the opposing surface thin film that is opposed to the hydrophilization region, to hydrophilize the hydrophilization region and the chip hydrophilization region;
a droplet attaching process of attaching a droplet to the hydrophilized hydrophilization region of the electronic component;
a self-alignment process of loading the hydrophilized chip hydrophilization region of the first semiconductor chip onto the droplet, and causing the chip hydrophilization region of the first semiconductor chip to self-align with respect to the hydrophilization region of the electronic component by surface tension of the droplet; and
a bonding process of bringing the hydrophilized chip hydrophilization region of the opposing surface thin film into contact with the hydrophilized hydrophilization region of the surface thin film to hydrophilically bond the hydrophilization region of the surface thin film and the chip hydrophilization region of the opposing surface thin film.

6. The bonding method according to claim 5, wherein
the hydrophilization region and the chip hydrophilization region are regions having a same external shape and smaller than an external shape of the first semiconductor chip.

7. The bonding method according to claim 6, further comprising:
a thermal diffusion bonding process, wherein
the electronic component comprises at least one electrode protruding from the surface,
the first semiconductor chip comprises at least one opposing electrode protruding from the opposing surface at a position opposed to each of the electrodes,
the thin film forming process coats the photoexcited hydrophilization reactant onto the surface to form the surface thin film with a thickness same as a protruding height of each of the electrodes in a region of the surface not including each of the electrodes, and coats the photoexcited hydrophilization reactant onto the opposing surface to form the opposing surface thin film with a thickness same as a protruding height of each of the opposing electrodes in a region of the opposing surface not including each of the opposing electrodes,
the hydrophilization process hydrophilizes the hydrophilization region of the surface thin film and the chip hydrophilization region of the opposing surface thin film,
the bonding process brings the hydrophilized chip hydrophilization region of the opposing surface thin film into contact with the hydrophilized hydrophilization region of the surface thin film to hydrophilically bond the hydrophilization region of the surface thin film and the chip hydrophilization region of the opposing surface thin film, and forms a bonding body in which each tip surface of each of the electrodes and each tip surface of each of the opposing electrodes are in contact with each other, and
the thermal diffusion bonding process heats the bonding body to bond, by thermal diffusion, each tip surface of each of the electrodes and each tip surface of each of the opposing electrodes which are in contact with each other.

8. The bonding method according to claim 6, further comprising:
a through electrode forming process of forming, in the electronic component formed with the surface thin film, at least one through electrode penetrating through the electronic component and the surface thin film in a thickness direction of the electronic component;
an opposing through electrode forming process of forming, in the first semiconductor chip formed with the opposing surface thin film, at least one opposing through electrode that penetrates through the first semiconductor chip and the opposing surface thin film in a thickness direction of the first semiconductor chip and is opposed to the through electrode; and
a thermal diffusion bonding process, wherein
the bonding process brings the hydrophilized chip hydrophilization region of the opposing surface thin film into contact with the hydrophilized hydrophilization region of the surface thin film to hydrophilically bond the hydrophilization region of the surface thin film and the chip hydrophilization region of the opposing surface thin film, and forms a bonding body in which each tip surface of each of the through electrodes and each tip surface of each of the opposing through electrodes are in contact with each other, and
the thermal diffusion bonding process heats the bonding body to bond, by thermal diffusion, each tip surface of each of the through electrodes and each tip surface of each of the opposing through electrodes which are in contact with each other.

9. The bonding method according to claim 5, wherein
the photoexcited hydrophilization reactant is selected from any one of titanium oxide, tungsten trioxide, silver bromide, silver chloride, silicon dioxide, nitrogen-doped silicon carbide, silicon nitride, or carbon-doped silicon monoxide,
the droplet is composed of a liquid selected from any one of hydrogen water, ozone water, carbon water, alkaline electrolytic water, or fine bubble water, and
the light is ultraviolet light.

10. The bonding method according to claim 5, wherein
the electronic component is a wafer, a second semiconductor chip different from the first semiconductor chip, or a substrate.

11. A semiconductor device obtained by bonding the electronic component and the first semiconductor chip by the bonding method according to claim 5.

12. An electronic component manufacturing system, which is an electronic component manufacturing system laminating and bonding a first semiconductor chip to a plate-shaped electronic component, the electronic component manufacturing system comprising:
a thin film forming apparatus, a hydrophilization apparatus, and a bonding apparatus, wherein
the thin film forming apparatus coats a photoexcited hydrophilization reactant onto a surface of the electronic component and an opposing surface of the first semiconductor chip that is opposed to the surface to form a surface thin film and an opposing surface thin film, and supplies the electronic component formed with the surface thin film and the first semiconductor chip formed with the opposing surface thin film to the hydrophilization apparatus,
the hydrophilization apparatus irradiates light onto a hydrophilization region, which is a part of the surface thin film, and a chip hydrophilization region of the opposing surface thin film that is opposed to the hydrophilization region to hydrophilize the hydrophilization region and the chip hydrophilization region, and supplies the hydrophilized electronic component and the hydrophilized first semiconductor chip to the bonding apparatus,
the bonding apparatus bonds the first semiconductor chip to the electronic component supplied from the hydrophilization apparatus, and comprises:
a stage that adsorbs and fixes the electronic component;
a collet that holds and releases the first semiconductor chip;
a dispenser that attaches a droplet to the surface of the electronic component;
a bonding head that moves the collet in each of a direction along the stage and a direction contacting and separating from the stage;
a dispenser head that moves the dispenser in each of a direction along the stage and a direction contacting and separating from the stage;
a pressing device that presses the first semiconductor chip against the electronic component adsorbed and fixed on the stage; and
a control part that adjusts operations of the collet, the dispenser, the bonding head, the dispenser head, and the pressing device, wherein
the control part comprises a processor that performs information processing, and
the processor is configured to:
attach, by the dispenser, the droplet to the hydrophilized hydrophilization region of the electronic component adsorbed and fixed on the stage,
load, by the collet, the hydrophilized chip hydrophilization region of the first semiconductor chip onto the droplet, and cause the chip hydrophilization region of the first semiconductor chip to self-align with respect to the hydrophilization region of the electronic component by surface tension of the droplet, and
press, by the pressing device, the hydrophilized chip hydrophilization region of the opposing surface thin film against the hydrophilized hydrophilization region of the surface thin film to hydrophilically bond the hydrophilization region of the surface thin film and the chip hydrophilization region of the opposing surface thin film.

13. The electronic component manufacturing system according to claim 12, wherein
the hydrophilization region and the chip hydrophilization region are regions having a same external shape and smaller than an external shape of the first semiconductor chip.

14. The electronic component manufacturing system according to claim 13, further comprising:
a heating apparatus, wherein
the electronic component comprises at least one electrode protruding from the surface,
the first semiconductor chip comprises at least one opposing electrode protruding from the opposing surface at a position opposed to each of the electrodes,
the thin film forming apparatus coats the photoexcited hydrophilization reactant onto the surface to form the surface thin film with a thickness same as a protruding height of each of the electrodes in a region of the surface not including each of the electrodes, and coats the photoexcited hydrophilization reactant onto the opposing surface to form the opposing surface thin film with a thickness same as a protruding height of each of the opposing electrodes in a region of the opposing surface not including each of the opposing electrodes,
the hydrophilization apparatus hydrophilizes the hydrophilization region of the surface thin film and the chip hydrophilization region of the opposing surface thin film,
the processor is configured to press, by the pressing device, the hydrophilized chip hydrophilization region of the opposing surface thin film against the hydrophilized hydrophilization region of the surface thin film to hydrophilically bond the hydrophilization region of the surface thin film and the chip hydrophilization region of the opposing surface thin film, and form a bonding body in which each tip surface of each of the electrodes and each tip surface of each of the opposing electrodes are in contact with each other, and
the heating apparatus heats the bonding body to bond, by thermal diffusion, each tip surface of each of the electrodes and each tip surface of each of the opposing electrodes which are in contact with each other.

15. The electronic component manufacturing system according to claim 13, further comprising:
an electrode forming apparatus; and
a heating apparatus, wherein
the thin film forming apparatus coats the photoexcited hydrophilization reactant onto the surface of the electronic component and the opposing surface of the first semiconductor chip that is opposed to the surface to form the surface thin film and the opposing surface thin film, and supplies the electronic component formed with the surface thin film and the first semiconductor chip formed with the opposing surface thin film to the electrode forming apparatus,
the electrode forming apparatus forms, in the electronic component formed with the surface thin film, at least one through electrode penetrating through the electronic component and the surface thin film in a thickness direction of the electronic component, and forms, in the first semiconductor chip formed with the opposing surface thin film, at least one opposing through electrode that penetrates through the first semiconductor chip and the opposing surface thin film in a thickness direction of the first semiconductor chip and is opposed to the through electrode,
the hydrophilization apparatus hydrophilizes the hydrophilization region of the surface thin film and the chip hydrophilization region of the opposing surface thin film,
the processor is configured to press, by the pressing device, the hydrophilized chip hydrophilization region of the opposing surface thin film against the hydrophilized hydrophilization region of the surface thin film to hydrophilically bond the hydrophilization region of the surface thin film and the chip hydrophilization region of the opposing surface thin film, and form a bonding body in which each tip surface of each of the through electrodes and each tip surface of each of the opposing through electrodes are in contact with each other, and
the heating apparatus heats the bonding body to bond, by thermal diffusion, each tip surface of each of the through electrodes and each tip surface of each of the opposing through electrodes which are in contact with each other.
